(19) United States
(12) Patent Application Publication
(10) Pub. No.: US 2026/0068658 A1
(43) Pub. Date: Mar. 5, 2026

(54) ADVANCED RF PACKAGING WITH AIR CAVITY FOR WIDE BANDGAP SEMICONDUCTORS AND DOUBLE-SIDED COOLING

(71) Applicant: Qorvo US, Inc., Greensboro, NC (US)

(72) Inventors: MD Hasnine, Richardson, TX (US); Neftali Salazar, Murphy, TX (US)

(21) Appl. No.: 19/303,832

(22) Filed: Aug. 19, 2025

Related U.S. Application Data
(60) Provisional application No. 63/688,577, filed on Aug. 29, 2024.

(51) Int. Cl. H01L 23/34; H01L 23/00; H01L 23/31; H01L 23/498; H01L 23/552; H01L 25/00; H01L 25/16; H04B 1/40

(52) U.S. Cl. CPC H01L 23/34; H04B 1/40

(57) ABSTRACT

The present disclosure relates to a radio frequency (RF) package with air cavities for wide bandgap semiconductors and double-sided cooling, and a process for making the same. The disclosed RF package includes a carrier board, an electrical module with a module substrate over the carrier board, an interposer over the module substrate, a flip-chip die, a heat spreader, a mold compound, a shielding structure covering the electrical module to provide a shielded module, and a heat sink over the shielded module. Herein, the flip-chip die is attached to the interposer, and the heat spreader is attached to the interposer to provide an air-cavity, within which the flip-chip die is located. The interposer, the flip-chip die, and the heat spreader are thermally coupled with each other. The mold compound resides over the module substrate and surrounds the interposer and the heat spreader without being in contact with the flip-chip die.

### RELATED APPLICATIONS

This application claims the benefit of provisional patent application Ser. No. 63/688,577, filed Aug. 29, 2024, the disclosure of which is hereby incorporated herein by reference in its entirety.

### FIELD OF THE DISCLOSURE

The present disclosure relates to a radio frequency (RF) package with one or more air cavities for wide bandgap semiconductors and double-sided cooling, and a process for making the same.

### BACKGROUND

With the popularity of portable electronic products in both consumer and military applications, three-dimensional (3D) packaging techniques as well as 2.5D packaging techniques are becoming more and more attractive in semiconductor packages to achieve highly compact integration of diverse components and functionalities. Yet, as electronic designs increasingly embrace 3D/2.5D packaging, thermal issues become more pronounced. Heat generation from densely stacked or side-by-side assembled multiple dies leads to elevated temperatures.

On the other hand, with faster switching speed, higher breakdown strength, and lower on-resistance, high-power radio frequency (RF) devices based on gallium nitride (GaN)/gallium arsenide (GaAs) technology significantly outperform silicon-based devices. To further enhance the breakdown voltage and maximum output power, it is desirable to decrease gate spacing of GaN/GaAs devices. As the gate spacing of the GaN/GaAs devices reduces, there is an increase in concentrated heat flux in the die bodies. Effectively managing device heating and controlling junction temperatures becomes essential, given their potential to negatively impact performance and reliability. In the case of the high-power RF devices attached to a package substrate, the ability to dissipate large amounts of heat through the package substrate underneath the devices (bottom-side cooling) is limited. This limitation results in high thermal resistance, ultimately degrading the device's lifetime. In addition, depending solely on heat sinks attached to the package substrate has been proven insufficient for dissipating highly concentrated heat flux.

Furthermore, in semiconductor packages, mold compounds are normally used to encapsulate electronic components (e.g., flip-chip dies, wire-bonding dies, and surface mounted devices) to protect the electronic components against damage from the outside environment. However, direct contact of the mold compounds and active component surfaces may adversely impact their electrical performance, especially for RF performance. Accordingly, it is desirable to package the RF electronic components in a configuration that is more appropriate for high frequency performance. An air-cavity packaging technique is a desired option, in which dry air provides a considerably lower dielectric constant than typical mold compounds, thus reducing losses and providing improved electrical performance at high frequencies.

Accordingly, there remains a need for improved package designs for advanced thermal management solutions, so as to facilitate utilization of the wide bandgap semiconductors (GaN, GaAs, and silicon carbide) in 3D/2.5D packaging configurations. In addition, air-cavity configurations for reduced losses and enhanced electrical performance are also desired in the improved package designs.

### SUMMARY

The present disclosure relates to a radio frequency (RF) package with one or more air cavities for wide bandgap semiconductors and double-sided cooling, and a process for making the same. The disclosed RF package includes a carrier board, an electronic module, a shielding structure, and a heat sink. The electronic module is attached to the carrier board via a number of contact structures and includes a module substrate, an interposer, a first flip-chip die, a first heat spreader, and a mold compound. The interposer is attached to a top surface of the module substrate, the first flip-chip die is attached to a top surface of the interposer, and a first heat spreader is attached to the top surface of the interposer to provide a first air-cavity, within which the first flip-chip die is located. The interposer, the first flip-chip die, and the first heat spreader are thermally coupled to each other. The mold compound resides on the top surface of the module substrate and surrounds the interposer and the first heat spreader without being in contact with the first flip-chip die. Herein, a top surface of the electronic module is composed of at least a top surface of the first heat spreader and a top surface of the mold compound, a side surface of the electronic module is a combination of a side surface of the mold compound and a side surface of the module substrate, and a bottom surface of the electronic module is a bottom surface of the module substrate. The shielding structure directly and completely covers the top surface of the electronic module and the side surface of the mold compound to provide a shielded module. The heat sink is formed over the shielded module.

In one embodiment of the RF package, the electronic module further includes a second flip-chip die and a second heat spreader. Herein, the second flip-chip die is attached to the top surface of the interposer, and the second heat spreader, separate from the first heat spreader, is attached to the top surface of the interposer to provide a second air-cavity, within which the second flip-chip die is located. The interposer, the second flip-chip die, and the second heat spreader are thermally coupled to each other. The mold compound surrounds the second heat spreader without being in contact with the second flip-chip die. The top surface of the electronic module is further composed of a top surface of the second heat spreader.

In one embodiment of the RF package, the first flip-chip die includes gallium nitride (GaN), gallium arsenide (GaAs), or silicon, while the second flip-chip die includes GaN, GaAs, or silicon.

In one embodiment of the RF package, the first flip-chip die includes a first die body, first interconnects extending outwardly from the first die body and coupled to the interposer via first solder caps, respectively, and first die vias extending through the first die body and coupled to corresponding first interconnects, respectively.

In one embodiment of the RF package, the electronic module further includes a first protection layer, which is located within the first air-cavity and at least encapsulates each of the first solder caps.

In one embodiment of the RF package, the first heat spreader includes a first lid and a first periphery wall that extends outwardly from a periphery of a bottom surface of the first lid and is attached to the top surface of the interposer, such that the first air-cavity is formed under the first lid and surrounded by the first periphery wall. The first lid is formed over and thermally coupled to a backside of the first flip-chip die, and the first periphery wall surrounds the first flip-chip die.

In one embodiment of the RF package, the interposer includes an interposer body and a number of interposer via structures, each of which is composed of a top via pad formed on a top surface of the interposer body, a through-silicon/silicon carbide via (TSV), and a bottom via pad formed on a bottom surface of the interposer body. Each TSV extends through the interposer body and is coupled between a corresponding top via pad on the top surface of the interposer body and a corresponding bottom via pad on the bottom surface of the interposer body. The interposer via structures are separate from each other and formed of an electrically and thermally conductive material. Certain ones of the interposer via structures are aligned with and thermally connected to the first periphery wall of the first heat spreader.

In one embodiment of the RF package, the bottom surface of the first lid of the first heat spreader is thermally attached to the backside of the first flip-chip die through a first sintered layer. The first periphery wall of the first heat spreader is attached to the certain ones of the interposer via structures through a first sintered component. Each of the first sintered layer and the first sintered component has a thermal conductivity larger than 60 W/m·K.

In one embodiment of the RF package, the electronic module further includes an extra flip-chip die attached to the backside of the first flip-chip die and located within the first air-cavity. The first lid is formed over a backside of the extra flip-chip die, and the first periphery wall surrounds a combination of the first flip-chip die and the extra flip-chip die. The interposer, the first flip-chip die, the extra flip-chip, and the first heat spreader are thermally coupled to each other.

In one embodiment of the RF package, the bottom surface of the first lid of the first heat spreader is thermally attached to the backside of the extra flip-chip die through the first sintered layer, which has a thermal conductivity larger than 60 W/m·K.

In one embodiment of the RF package, the first flip-chip die includes the first die body, the first interconnects extending outwardly from the first die body and coupled to certain other ones of the interposer via structures through the first solder caps, respectively, the first die vias extending through the first die body and coupled to the corresponding first interconnects, respectively, and die via pads formed on the top surface of the first die body and coupled to corresponding first die vias, respectively. The extra flip-chip die includes a die body, interconnects extending outwardly from the die body and coupled to corresponding die via pads on the top surface of the first die body through solder caps, respectively, and die vias extending through the die body of the extra flip-chip die and coupled to corresponding interconnects of the extra flip-chip die, respectively.

In one embodiment of the RF package, the electronic module further includes the first protection layer and an extra protection layer. The first protection layer is located within the first air-cavity and at least encapsulates each of the first solder caps, while the extra protection layer is located within the first air-cavity and at least encapsulates each of the solder caps of the extra flip-chip die.

In one embodiment of the RF package, the first heat spreader is formed of silicon carbide.

In one embodiment of the RF package, the first heat spreader is at least 1.5 times larger than the first flip-chip die in horizontal dimensions.

In one embodiment of the RF package, the module substrate is a laminate-based substrate.

In one embodiment of the RF package, the shielding structure includes multiple layers and is formed of stainless steel and copper.

In one embodiment of the RF package, the contact structures are configured as a Ball Grid Array (BGA).

In one embodiment of the RF package, the contact structures are configured as a Land Grid Array (LGA).

According to one embodiment, a communication device includes a control system, a baseband processor, receive circuitry, and transmit circuitry. At least one or any combination of the control system, the baseband processer, the transmit circuitry, and the receive circuitry is implemented in an RF package, which has a carrier board, an electronic module attached to the carrier board via a number of contact structures, a shielding structure, and a heat sink. The electronic module includes a module substrate, an interposer, a first flip-chip die, a first heat spreader, and a mold compound. The interposer is attached to a top surface of the module substrate, the first flip-chip die is attached to a top surface of the interposer, and a first heat spreader is attached to the top surface of the interposer to provide a first air-cavity, within which the first flip-chip die is located. The interposer, the first flip-chip die, and the first heat spreader are thermally coupled to each other. The mold compound resides on the top surface of the module substrate and surrounds the interposer and the first heat spreader without being in contact with the first flip-chip die. Herein, a top surface of the electronic module is composed of at least a top surface of the first heat spreader and a top surface of the mold compound, a side surface of the electronic module is a combination of a side surface of the mold compound and a side surface of the module substrate, and a bottom surface of the electronic module is a bottom surface of the module substrate. The shielding structure directly and completely covers the top surface of the electronic module and the side surface of the mold compound to provide a shielded module. The heat sink is formed over the shielded module.

According to one embodiment, a method of fabricating an RF package starts with forming an electronic module, which includes a module substrate, an interposer, a first flip-chip die, a first heat spreader, and a mold compound. The interposer is attached to a top surface of the module substrate, the first flip-chip die is attached to a top surface of the interposer, and a first heat spreader is attached to the top surface of the interposer to provide a first air-cavity, within which the first flip-chip die is located. The interposer, the first flip-chip die, and the first heat spreader are thermally coupled to each other. The mold compound resides on the top surface of the module substrate and surrounds the interposer and the first heat spreader without being in contact with the first flip-chip die, such that a top surface of the electronic module is composed of at least a top surface of the first heat spreader and a top surface of the mold compound, a side surface of the electronic module is a combination of a side surface of the mold compound and a side surface of the module substrate, and a bottom surface of the electronic module is a bottom surface of the module substrate. Next, a shielding structure is formed directly and completely over the top surface of the electronic module and the side surface of the mold compound to provide a shielded module. The shielded module is then attached to a carrier board via a number of contact structures. The contact structures are configured as a BGA or an LGA.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIGS. 1A-1B illustrate an exemplary radio frequency (RF) package with a 2.5D configuration according to some embodiments of the present disclosure.

FIGS. 2A-2B illustrate the RF package with a 3D configuration according to some embodiments of the present disclosure.

FIGS. 3-14B illustrate steps of a process of fabricating the RF packages shown in FIGS. 1A and 1B according to some embodiments of the present disclosure.

FIGS. 15-28B illustrate steps of a process of fabricating the alternative RF packages shown in FIGS. 2A and 2B according to some embodiments of the present disclosure.

FIG. 29 is a block diagram of a communication device, which may include one RF package illustrated in FIGS. 1A, 1B, 2A, or 2B according to some embodiments of the present disclosure.

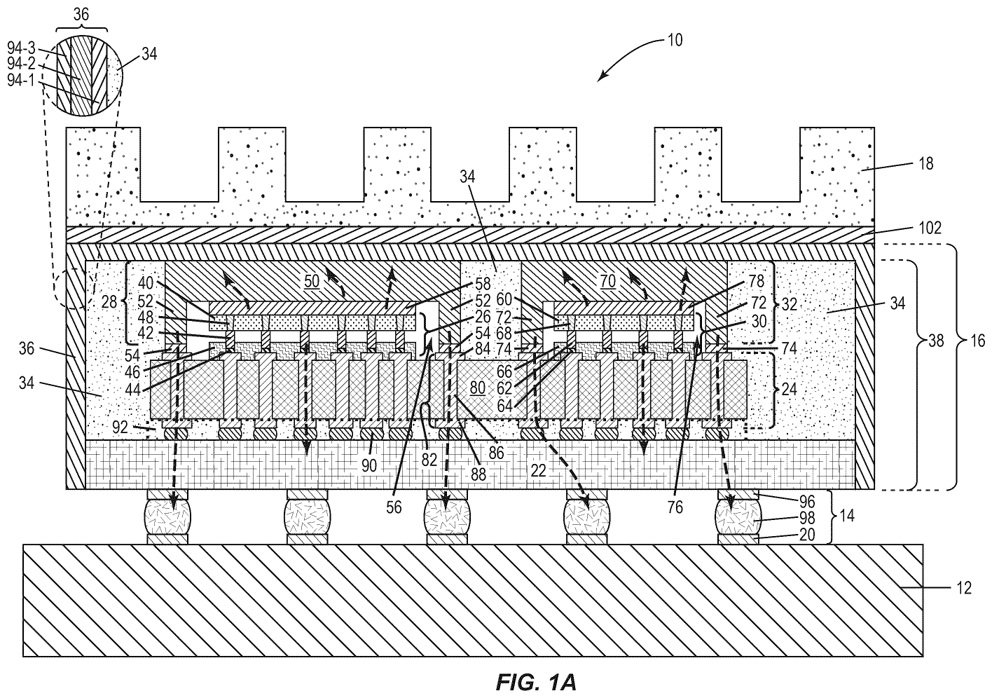

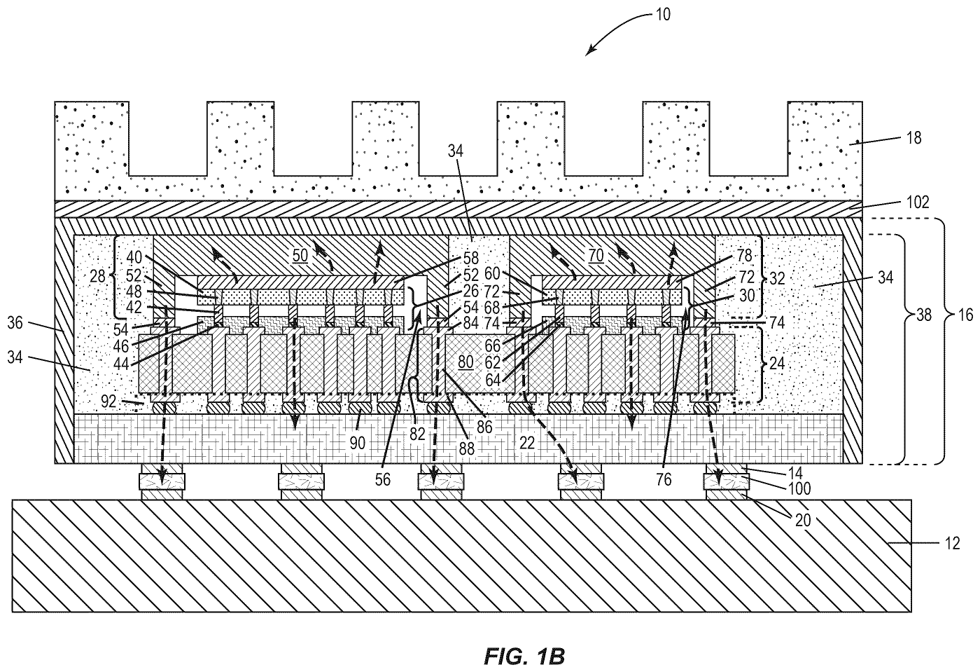

It will be understood that for clear illustrations, FIGS. 1A-29 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

For high-power radio frequency (RF) devices, such as gallium nitride (GaN)/gallium arsenide (GaAs) devices, bottom-side cooling through a package laminate substrate is limited, which may negatively impact electrical performance and device reliability. Top-side cooling for the high-power RF devices is imperative to establish as an additional thermal pathway to an ambient environment. Compared to wire-bonding dies, flip-chip assembly technology, besides its preferable solder interconnection to the package substrate (which helps in reducing the die size, reducing the overall size of the package, shorting the electrical path to the package laminate substrate, and reducing undesired inductance and capacitance), also provides the capability for the top-side cooling. A backside of one flip chip die (referring to an end surface away from an active region of the flip-chip die and opposite the die solder balls/die copper pillars) is typically inactive, which allows the backside of the flip chip die to be connected to a high thermally conductive component above, so as to provide an upward heat dissipation path.

In addition, three-dimensional (3D)/2.5D packaging techniques enable integration of multiple dies to achieve electronics densification in a small footprint. To enhance cooling efficiency for the multiple dies within the 3D/2.5D packaging configuration, oversized heat spreaders are introduced to the dies (e.g., attached atop the die, more details are described below). Furthermore, usage of air cavities is desirable for certain RF devices in packaging configurations, where the dielectric property of air compared to the mold compound may give performance advantages.

FIGS. 1A-1B illustrate an exemplary RF package 10 with a 2.5D configuration, which includes air cavities and enables efficient thermal paths for both top-side cooling and bottom-side cooling, according to some embodiments of the present disclosure. The RF package 10 includes a carrier board 12, contact structures 14 (only one contact structure is labeled with a reference number for clarity), a shielded module 16, and a heat sink 18. Herein, the shielded module 16 is coupled to the carrier board 12 via the contact structures 14, while the heat sink 18 resides over the shielded module 16.

The carrier board 12 may be a printed circuit board (PCB) that is made from FR4 or similar material and includes carrier connectors 20 (only one carrier connector is labeled with a reference number for clarity) on a top surface of the carrier board 12. The carrier connectors 20 are configured to accommodate the contact structures 14, respectively. The contact structures 14 are configured to electrically and thermally connect the shielded module 16 to the carrier board 12.

For the purpose of this illustration, the shielded module 16 includes a module substrate 22, an interposer 24, a first flip-chip die 26 with a first heat spreader 28, a second flip-chip die 30 with a second heat spreader 32, a mold compound 34, and a shielding structure 36. The interposer 24 is attached to a top surface of the module substrate 22. Both the first flip-chip die 26 and the second flip-chip die 30 are attached to a top surface of the interposer 24. The first heat spreader 28 and the second heat spreader 32 are separate from each other, coupled to the top surface of the interposer 24, and encapsulate the first flip-chip die 26 and the second flip-chip die 30, respectively. The mold compound 34 resides over the top surface of the module substrate 22 and surrounds the interposer 24, the first heat spreader 28, and the second heat spreader 32. A combination of the module substrate 22, the interposer 24, the first flip-chip die 26, the first heat spreader 28, the second flip-chip die 30, the second heat spreader 32, and the mold compound 34 constitutes an electronic module 38. The shielding structure 36 directly and completely covers a top surface of the electronic module 38 and directly covers a majority of a side surface of the electronic module 38 (more details are described below), while a bottom surface of the electronic module 38 (i.e., a bottom surface of the module substrate 22) is exposed. In different applications, the shielded module 16 may include fewer or more flip-chip dies attached to the top surface of the interposer 24 and may be encapsulated by corresponding fewer or more heat spreaders, respectively.

In detail, the first flip-chip die 26 includes a first die body 40 and multiple first interconnects 42 extending outwardly from a bottom surface of the first die body 40 and coupled to the top surface of the interposer 24. An active region (not shown) of the first flip-chip die 26 is located at a bottom portion of the first die body 40 and adjacent to the first interconnects 42. The first die body 40 may be formed from GaN with silicon carbide (SiC), GaAs with SiC, silicon, or any appropriate semiconductor material(s), and the first interconnects 42 may be copper pillars that are coupled to the interposer 24 via first solder caps 44, respectively (only one first interconnect and one first solder cap of the first flip-chip die 26 are labeled with reference numbers for clarity and simplicity).

To ensure the integrity of the first solder caps 44 during a sintering process (more details are described below), each first solder cap 44 may be encapsulated by a first protection layer 46. The first protection layer 46 is formed on the top surface of the interposer 24, and covers each first solder cap 44 and at least a bottom portion of each first interconnect 42. Herein, the unencapsulated portion of each first interconnect 42 is typically a majority of each first interconnect 42, thus the first protection layer 46 has a low impact on electrical signals propagating from the first flip-chip die 26 to the interposer 24 and vice-versa. The first protection layer 46 may be formed of an epoxy material.

In some embodiments, the first flip-chip die 26 includes multiple first die vias 48 extending through the first die body 40 and coupled to corresponding first interconnects 42, respectively (only one first die via of the first flip-chip die 26 is labeled with a reference number for clarity and simplicity). The first die vias 48 are configured to dissipate heat generated in the first die body 40 (e.g., heat generated by the active region of the first flip-chip die 26) towards a backside of the first flip-chip die 26, which enables top-side cooling of the first flip-chip die 26, and towards the first interconnects 42 of the first flip-chip die 26, which enables down-side cooling of the first flip-chip die 26. Herein and hereafter, a backside surface of one flip-chip die refers to a surface away from an active region of the flip-chip die and opposite the die interconnects. In some cases, the backside of the first flip-chip die 26 may be metalized (e.g., a plated metal film) as a grounding plane (not shown for simplicity).

The first heat spreader 28 is an oversized heat spreader, which is at least 1.5 times (e.g., 2-5 times) larger than the first flip-chip die 26 in horizontal dimensions, and is formed of a material with a high thermal conductivity, such as SiC. The first heat spreader 28 includes a first lid 50 over the first flip-chip die 26 and a first periphery wall 52, which extends outwardly from a periphery of a bottom surface of the first lid 50 and towards the top surface of the interposer 24 and surrounds the first flip-chip die 26. The first periphery wall 52 is continuous and connected to the top surface of the interposer 24 through a first sintered component 54. As such, a first air-cavity 56, within which the first flip-chip die 26 and the first protection layer 46 are located, is formed under the first lid 50 (i.e., between the bottom surface of the first lid 50 and the top surface of the interposer 24) and is surrounded by the first periphery wall 52 (i.e., the first periphery wall 52 defines a perimeter of the first air-cavity 56).

In particular, the backside of the first flip-chip die 26 (i.e., a top surface of the first die body 40) is connected to the bottom surface of the first lid 50 through a first sintered layer 58, while the active region of the first flip-chip die 26 (located at a bottom surface of the first die body 40) is exposed to the first air-cavity 56. The first sintered component 54 and the first sintered layer 58 may be formed of a sintering material with a high thermal conductivity (larger than 60 W/m·K, e.g., between 60 W/m·K and 75 W/m·K), such as sintering silver or sintering copper.

Herein, the heat generated in the first flip-chip die 26 (e.g., the heat generated by the active region of the first flip-chip die 26 located at the bottom portion of the first die body 40) can be dissipated upward through the first die vias 48, the first sintered layer 58, and the first lid 50 of the first heat spreader 28, and also be dissipated downward through the first die vias 48 and the first interconnects 42 towards the interposer 24. In addition, the heat generated in the first flip-chip die 26 may also be dissipated from the first die vias 48, the first sintered layer 58, the first lid 50, and the first periphery wall 52 towards the interposer 24. Since the first heat spreader 28 is oversized and at least 1.5 times larger than the first flip-chip die 26, the heat generated in the first flip-chip die 26 can also be dissipated laterally by the first die vias 48, the first sintered layer 58, and the first lid 50, such that the concentrated heat flux in the first die body 40 can be relieved. Moreover, the first periphery wall 52 is configured to provide structural/mechanical support for the oversized first heat spreader 28 and may mitigate deformation risk of the first flip-chip die 26 during a molding process (more details are described below). In addition, the exposure of the bottom surface of the first die body 40 as well as the majority of each first interconnect 42 to the first air-cavity 56 is beneficial for electronic performance of the first flip-chip die 26, especially for high-frequency performance.

Similarly, the second flip-chip die 30 includes a second die body 60 and multiple second interconnects 62 extending outwardly from a bottom surface of the second die body 60 and coupled to the top surface of the interposer 24. An active region (not shown) of the second flip-chip die 30 is located at a bottom portion of the second die body 60 and adjacent to the second interconnects 62. The second die body 60 may be formed from GaN with SiC, GaAs with SiC, silicon, or any appropriate semiconductor material(s), and the second interconnects 62 may be copper pillars that are coupled to the interposer 24 via second solder caps 64, respectively (only one second interconnect and one second solder cap of the second flip-chip die 30 are labeled with reference numbers for clarity and simplicity).

To ensure the integrity of the second solder caps 64 during a sintering process (more details are described below), each second solder cap 64 may be encapsulated by a second protection layer 66. The second protection layer 66 is formed on the top surface of the interposer 24 and covers each second solder cap 64 and at least a bottom portion of each second interconnect 62. Herein, the unencapsulated portion of each second interconnect 62 is typically a majority of each second interconnect 62, thus the second protection layer 66 has a low impact on electrical signals propagating from the second flip-chip die 30 to the interposer 24 and vice-versa. The second protection layer 66 may be formed of an epoxy material.

In some embodiments, the second flip-chip die 30 includes multiple second die vias 68 extending through the second die body 60 and coupled to corresponding second interconnects 62, respectively (only one second die via of the second flip-chip die 30 is labeled with a reference number for clarity and simplicity). The second die vias 68 are configured to dissipate heat generated in the second die body 60 (e.g., heat generated by the active region of the second flip-chip die 30) towards a backside of the second flip-chip die 30, which enables top-side cooling of the second flip-chip die 30, and towards the second interconnects 62 of the second flip-chip die 30, which enables down-side cooling of the second flip-chip die 30. In some cases, the backside of the second flip-chip die 30 may be metalized (e.g., a plated metal film) as a grounding plane (not shown for simplicity).

The second heat spreader 32 is an oversized heat spreader, which is at least 1.5 times larger than the second flip-chip die 30 in horizontal dimensions, and is formed of a material with a high thermal conductivity, such as SiC. The second heat spreader 32 includes a second lid 70 over the second flip-chip die 30 and a second periphery wall 72, which extends outwardly from a periphery of a bottom surface of the second lid 70 and towards the top surface of the interposer 24 and surrounds the second flip-chip die 30. The second periphery wall 72 is continuous and connected to the top surface of the interposer 24 through a second sintered component 74. As such, a second air-cavity 76, within which the second flip-chip die 30 and the second protection layer 66 are located, is formed under the second lid 70 (i.e., between the bottom surface of the second lid 70 and the top surface of the interposer 24) and is surrounded by the second periphery wall 72 (i.e., the second periphery wall 72 defines a perimeter of the second air-cavity 76).

In particular, the backside of the second flip-chip die 30 (i.e., a top surface of the second die body 60) is connected to the bottom surface of the second lid 70 through a second sintered layer 78, while the active region of the second flip-chip die 30 (located at a bottom surface of the second die body 60) is exposed to the second air-cavity 76. The second sintered component 74 and the second sintered layer 78 may be formed of a sintering material with a high thermal conductivity (larger than 60 W/m·K, e.g., between 60 W/m·K and 75 W/m·K), such as sintering silver or sintering copper.

Herein, the heat generated in the second flip-chip die 30 (e.g., the heat generated by the active region of the second flip-chip die 30 located at the bottom portion of the second die body 60) can be dissipated upward through the second die vias 68, the second sintered layer 78, and the second lid 70 of the second heat spreader 32, and also be dissipated downward through the second die vias 68, and the second interconnects 62 towards the interposer 24. In addition, the heat generated in the second flip-chip die 30 may also be dissipated from the second die vias 68, the second sintered layer 78, the second lid 70, and the second periphery wall 72 towards the interposer 24. Since the second heat spreader 32 is oversized and at least 1.5 times larger than the second flip-chip die 30, the heat generated in the second flip-chip die 30 can also be dissipated laterally by the second die vias 68, the second sintered layer 78, and the second lid 70, such that the concentrated heat flux in the second die body 60 can be relieved. Moreover, the second periphery wall 72 is configured to provide structural/mechanical support for the oversized second heat spreader 32 and may mitigate deformation risk of the second flip-chip die 30 during a molding process (more details are described below). In addition, the exposure of the bottom surface of the second die body 60 as well as the majority of each second interconnect 62 to the second air-cavity 76 is beneficial for electronic performance of the second flip-chip die 30, especially for high-frequency performance.

The interposer 24 includes an interposer body 80 and multiple interposer via structures 82, each of which is composed of a top via pad 84, a through-silicon/silicon carbide via (TSV) 86, and a bottom via pad 88 (only one interposer via structure, one top via pad, one TSV, and one bottom via pad are labeled with reference numbers for clarity and simplicity). Each TSV 86 extends through the interposer body 80, and is coupled to a corresponding top via pad 84 formed on a top surface of the interposer body 80 and to a corresponding bottom via pad 88 formed on a bottom surface of the interposer body 80. The interposer via structures 82 are separate from each other and are formed of an electrically and thermally conductive material, such as copper. The interposer body 80 may be formed of a semiconductor material, such as silicon or SiC.

Herein, each interposer via structure 82 is coupled to and aligned with one of the first interconnects 42 of the first flip-chip die 26, the first periphery wall 52 of the first heat spreader 28, one of the second interconnects 62 of the second flip-chip die 30, or the second periphery wall 72 of the second heat spreader 32. In particular, each first interconnect 42 of the first flip-chip die 26 is electrically and thermally connected to one top via pad 84 of a corresponding interposer via structure 82 through one first solder cap 44, while each second interconnect 62 of the second flip-chip die 30 is electrically and thermally connected to one top via pad 84 of a corresponding interposer via structure 82 through one second solder cap 64. In addition, the first periphery wall 52 of the first heat spreader 28 is thermally connected to multiple top via pads 84 of corresponding interposer via structures 82 through the first sintered component 54. Note that the first sintered component 54 is a continuous component corresponding to the continuous first periphery wall 52, such that the first sintered component 54 also connects the first periphery wall 52 to portions of the top surface of the interposer body 80 exposed through gaps between the corresponding top via pads 84 (underneath the first periphery wall 52, not shown). Similarly, the second periphery wall 72 of the second heat spreader 32 is thermally connected to multiple top via pads 84 of other corresponding interposer via structures 82 through the second sintered component 74. The second sintered component 74 is a continuous component corresponding to the continuous second periphery wall 72, such that the second sintered component 74 also connects the second periphery wall 72 to other portions of the top surface of the interposer body 80 exposed through gaps between the corresponding top via pads 84 (underneath the second periphery wall 72, not shown).

In one embodiment, the interposer 24 is attached to the module substrate 22 through solder joints 90 (only one solder joint is labeled with a reference number for clarity and simplicity). Herein, the bottom via pad 88 of each interposer via structures 82 is attached to the top surface of the module substrate 22 through a corresponding solder joint 90. The interposer 24 may be underfilled by an underfilling material 92, such as an epoxy material, which encapsulates each solder joint 90 and each bottom via pad 88, and fills gaps between the bottom surface of the interposer body 80 and the top surface of the module substrate 22. The underfilling material 92 is configured to ensure the integrity of the solder joints 90 during a sintering process (more details are described below).

The module substrate 22 might be a laminate-base substrate, which is composed of organic materials (e.g., FR4) and metal structures (e.g., layers, pads, traces, vias, etc.) used to form internal connections within the organic materials (not shown) and/or electrical/thermal connections to external components (e.g., connection to the interposer 24, not shown). As such, heat generated in the first flip-chip die 26 and the second flip-chip die 30 can be further dissipated downward to the module substrate 22 through the interposer 24 (especially through the interposer via structures 82). Note that the interposer via structures 82 vertically between the first flip-chip die 26/the second flip-chip die 30 and the module substrate 22 are configured to transmit both electrical signals and provide a thermal path, while the interposer via structures 82 vertically between the first periphery wall 52/the second periphery wall 72 and the module substrate 22 are configured to only dissipate heat.

The mold compound 34 is formed over the module substrate 22 and around the interposer 24, the first heat spreader 28, and the second heat spreader 32. The mold compound 34 is not in contact with the first flip-chip die 26 or the second flip-chip die 30. A top surface of the first heat spreader 28 (i.e., a top surface of the first lid 50) and a top of the second heat spreader 32 (i.e., a top surface of the second lid 70) are not covered by the mold compound 34, and are coplanar with a top surface of the mold compound 34. The electronic module 38, which is composed of the module substrate 22, the interposer 24, the first flip-chip die 26, the first heat spreader 28, the second flip-chip die 30, the second heat spreader 32, and the mold compound 34, has a top surface that is a combination of the top surface of the first heat spreader 28, the top of the second heat spreader 32 and the top surface of the mold compound 34. The electronic module 38 has a side surface that is a combination of a side surface of the mold compound 34 and a side surface of the module substrate 22, and has a bottom surface that is the bottom surface of the module substrate 22.

The shielding structure 36 directly and completely covers a top surface of the electronic module 38 and directly covers a majority of the side surface of the electronic module 38 (e.g., directly and completely covers the side surface of the mold compound 34, or directly and completely covers the side surface of the electronic module 38) to form the shielded module 16. The shielding structure 36 is configured to improve hermeticity and integrity of the first and second heat spreaders 28 and 32. In one embodiment, the shielding structure 36 includes a first shielding layer 94-1 that directly and completely covers the top surface and the side surface of the electronic module 38, a second shielding layer 94-2 that directly and completely covers the first shielding layer 94-1, and a third shielding layer 94-3 that directly and completely covers the second shielding layer 94-2. The first and third shielding layers 94-1 and 94-3 might be formed of stainless steel or other proper conductive materials, while the second shielding layer 94-2 might be formed of copper or other proper conductive materials.

A bottom surface of the shielded module 16 (i.e., the bottom surface of the electronic module 38) is not covered by the shielding structure 36 and is exposed to the top surface of the carrier board 12. The shielded module 16 is attached to the carrier board 12 through the contact structures 14. As such, the heat generated by the first flip-chip die 26 and the second flip-chip die 30 can be further dissipated downward from the module substrate 22 towards the carrier board 12 through the contact structures 14. In different applications, the contact structures 14 may be implemented differently. As shown in FIG. 1A, each contact structure 14 may include a substrate pad 96 and a reflowed solder ball 98, which is connected to a corresponding carrier connector 20. As such, the shielded module 16 is attached to the carrier board 12 using a Ball Grid Array (BGA). In some cases, each contact structure 14 may be a metal pad, which is connected to a corresponding carrier connector 20 via a solder paste 100. As such, the shielded module 16 is attached to the carrier board 12 using a Land Grid Array (LGA), as shown in FIG. 1B.

In addition, the heat sink 18 is attached to a top surface of the shielded module 16 (i.e., a portion of the shielding structure 36 vertically above the top surface of the electronic module 38) through an adhesion layer 102, which is thermally conductive, such as a thermal gel, grease or paste. Accordingly, the heat generated by the first flip-chip die 26 and the second flip-chip die 30 can be dissipated further upward from the first lid 50 of the first heat spreader 28 and the second lid 70 of the second heat spreader 32 to the heat sink 18. This 2.5D packaging arrangement with the interposer 24 and the oversized heat spreaders 28/32 can efficiently conduct heat from the first and second flip-chip dies 26 and 30 (upward to the heat sink 18 and downward to the carrier board 12), resulting in a significant reduction in junction temperature within the RF package 10.

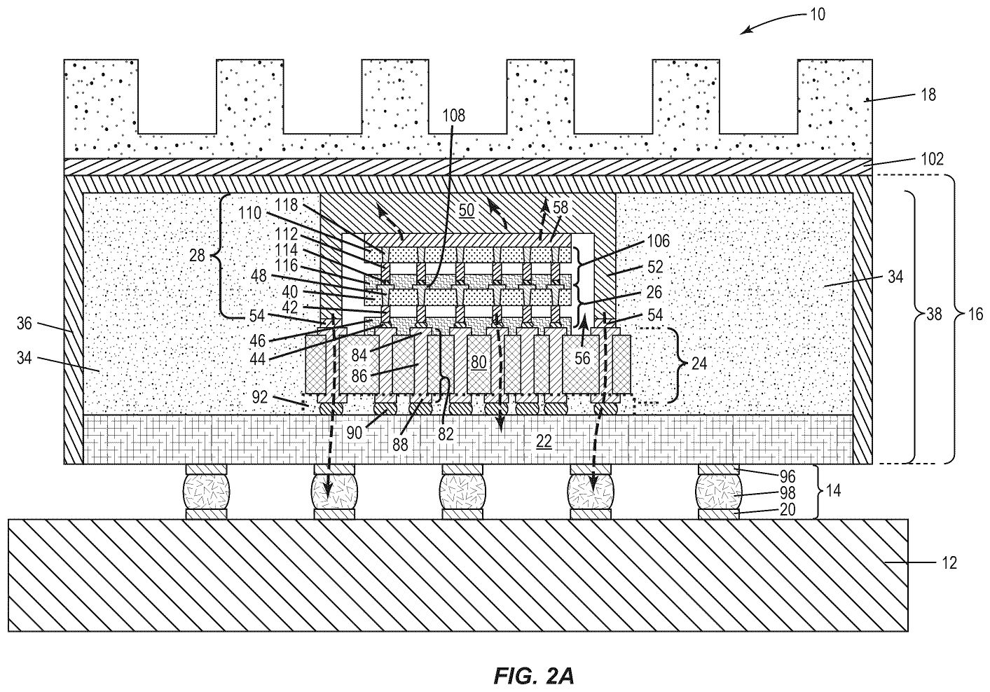

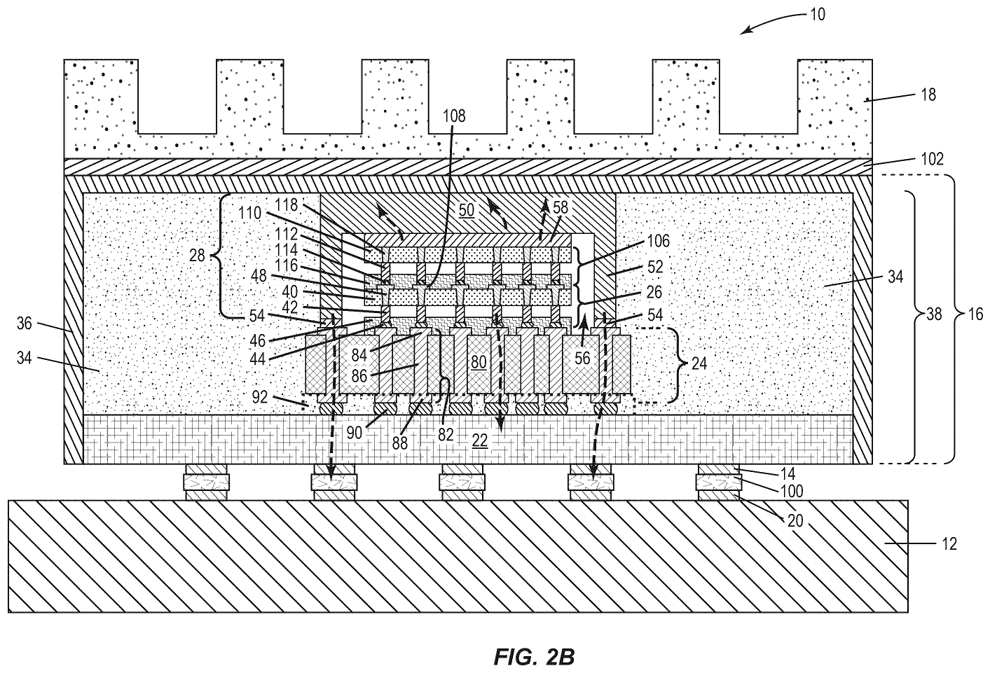

In some applications, the RF package 10 has a 3D configuration, in which two or more semiconductor dies are vertically stacked, as illustrated in FIGS. 2A and 2B. Herein, the shielded module 16 is still coupled to the carrier board 12 via the contact structures 14 (each contact structure 14 may be configured as a BGA as shown in FIG. 2A, or configured as an LGA as shown in FIG. 2B), while the heat sink 18 still resides over the shielded module 16. The shielded module 16 is still composed of the electronic module 38 and the shielding structure 36, while the electronic module 38, in addition to the interposer 24 vertically stacked with one or more flip-chip dies, also includes a die-stacked configuration.

For the purpose of this illustration, the electronic module 38 includes the module substrate 22, the interposer 24, the first flip-chip die 26, an extra flip-chip die 106 vertically stacked with the first flip-chip die 26, the first heat spreader 28 covering both the first flip-chip die 26 and the extra flip-chip die 106, and the mold compound 34. The interposer 24 is still attached to the top surface of the module substrate 22 through the solder joint 90 (as described above), and the first heat spreader 28 is still attached to the top surface of the interposer 24 through the first sintered component 54, so as to provide the first air-cavity 56 (as described above). The mold compound 34 still resides over the top surface of the module substrate 22 and surrounds the interposer 24 and the first heat spreader 28 without covering the top surface of the first heat spreader 28 (i.e., the top surface of the first heat spreader 28/the first lid 50 is coplanar with the top surface of the mold compound 34, as described above).

Herein, within the first air-cavity 56, the first flip-chip die 26 is still attached to the top surface of the interposer 24 through the first solder caps 44 (as described above), while the extra flip-chip die 106 is attached to the backside of the first flip-chip die 26 (i.e., the top surface of the first die body 40). In order to accommodate the attachment of the extra flip-chip die 106, the first flip-chip die 26 may include die via pads 108 on the backside of the first flip-chip die 26 (i.e., the top surface of the first die body 40 of the first flip-chip die 26). The die via pads 108 may be formed by selectively etching the plated metal film on the backside of the first flip-chip die 26.

The extra flip-chip die 106 includes a die body 110 and multiple interconnects 112, that extend outwardly from a bottom surface of the die body 110 and are coupled to the backside of the first flip-chip die 26. An active region (not shown) of the extra flip-chip die 106 is located at a bottom portion of the die body 110 and adjacent to the interconnects 112. In detail, the die body 110 of the extra flip-chip die 106 may be formed from GaN with SiC, GaAs with SiC, silicon, or any appropriate semiconductor material(s), and each interconnect 112 may be a copper pillar and is coupled to a corresponding die via pad 108 via a solder cap 114 (only one interconnect and one solder cap of the extra flip-chip die 106 are labeled with reference numbers for clarity and simplicity). The number and location of the die via pads 108 on the backside of the first flip-chip die 26 correspond to the number and horizontal arrangement of the interconnects 112 of the extra flip-chip die 106. In one embodiment, each die via pad 108 is directly formed over a corresponding first die via 48 within the first die body 40 of the first flip-chip die 26, and is aligned with and coupled to a corresponding interconnect 112 of the extra flip-chip die 106.

To ensure the integrity of the solder caps 114 of the extra flip-chip die 106 during a sintering process (more details are described below), each solder cap 114 may be encapsulated by an extra protection layer 116. The extra protection layer 116 is formed on the backside of the first flip-chip die 26 and covers each die via pad 108, each solder cap 114, and at least a bottom portion of each interconnect 112. Herein, the unencapsulated portion of each interconnect 112 of the extra flip-chip die 106 is typically a majority of each interconnect 112, thus the extra protection layer 116 has a low impact on electrical signals propagating from the extra flip-chip die 106 to the first flip-chip die 26 and vice-versa. The extra protection layer 116 may be formed of an epoxy material.

In some embodiments, the extra flip-chip die 106 includes multiple die vias 118 extending through the die body 110 and coupled to corresponding interconnects 112, respectively (only one die via of the extra flip-chip die 106 is labeled with a reference number for clarity and simplicity). The die vias 118 are configured to dissipate heat generated in the die body 110 of the extra flip-chip die 106 towards a backside of the extra flip-chip die 106, which enables top-side cooling of the extra flip-chip die 106, and towards the interconnects 112 of the extra flip-chip die 106, which enables down-side cooling of the extra flip-chip die 106. In some cases, the backside of the extra flip-chip die 106 may be metalized (e.g., a plated metal film) as a grounding plane (not shown for simplicity).

Compared to the extra flip-chip die 106, the first heat spreader 28 is also oversized, which is at least 1.5 times larger than the extra flip-chip die 106 in horizontal dimensions. The backside of the extra flip-chip die 106 is connected to the bottom surface of the first lid 50 of the first heat spreader 28 through the first sintered layer 58. Both the active region of the extra flip-chip die 106 and the active region of the first flip-chip die 26 are exposed to the first air-cavity 56. Herein, the heat generated in the extra flip-chip die 106 can be dissipated upward through the die vias 118 of the extra flip-chip die 106, the first sintered layer 58, and the first lid 50 of the first heat spreader 28 to the heat sink 18 (through the shielding structure 36 and the adhesion layer 102), and also be dissipated downward through the die vias 118 and the interconnects 112 of the extra flip-chip die 106, the solder caps 114, the first flip-chip die 26 (i.e., through the die via pads 108, the first die vias 48, and the first interconnects 42 of the first flip-chip die 26), the first solder caps 44, the interposer 24 (i.e., the interposer via structures 82), the solder joint 90, the module substrate 22, and the contact structures 14 to the carrier board 12. In addition, the heat generated in the extra flip-chip die 106 may also be dissipated from the die vias 118 of the extra flip-chip die 106, the first sintered layer 58, the first lid 50 of the first heat spreader 28, the first periphery wall 52 of the first heat spreader 28, the first sintered component 54, the interposer 24 (i.e., the interposer via structures 82), the solder joint 90, the module substrate 22, and the contact structures 14 to the carrier board 12. Since the first heat spreader 28 is oversized and at least 1.5 times larger than the extra flip-chip die 106, the heat generated in the extra flip-chip die 106 can also be dissipated laterally by the die vias 118, the first sintered layer 58, and the first lid 50 of the first heat spreader, such that the concentrated heat flux in the die body 40 of the extra flip-chip die 106 can be relieved.

On the other hand, the heat generated in the first flip-chip die 26 can be dissipated downward as described above, and also be dissipated upward through the first die vias 48 and the die via pads 108 of the first flip-chip die 26, the solder caps 114, the extra flip-chip die 106 (i.e., through the interconnects 112 and the die vias 118 of the extra flip-chip die 106), the first sintered layer 58, and the first lid 50 of the first heat spreader 28 to the heat sink 18. In addition, the heat generated in the first flip-chip die 26 may also be dissipated through the first die vias 48 and the die via pads 108 of the first flip-chip die 26, the extra flip-chip die 106 (i.e., through the interconnects 112 and the die vias 118 of the extra flip-chip die 106), the first sintered layer 58, the first lid 50 of the first heat spreader 28, the first periphery wall 52 of the first heat spreader 28, the first sintered component 54, the interposer 24 (i.e., the interposer via structures 82), the solder joint 90, the module substrate 22, and the contact structures 14 to the carrier board 12.

This 3D packaging arrangement (the die-stacked configuration) and the oversized first heat spreader 28 can efficiently conduct heat from the first and extra flip-chip dies 26 and 106 (upward to the heat sink 18 and downward to the carrier board 12), resulting in a significant reduction in junction temperature within the RF package 10. Moreover, the oversized first heat spreader 28 is configured to provide the sealed air-cavity, in which the first flip-chip die 26 and the extra flip-chip die 106 are located in and exposed, to facilitate electronic performance of the first flip-chip die 26 and the extra flip-chip die 106, especially for high-frequency performance. The first periphery wall 52 of the first heat spreader 28 also provides structural/mechanical support for the first lid 50 of the first heat spreader 28 and may mitigate deformation risk of the extra flip-chip die 106 and the first flip-chip die 26 during a molding process (more details are described below).

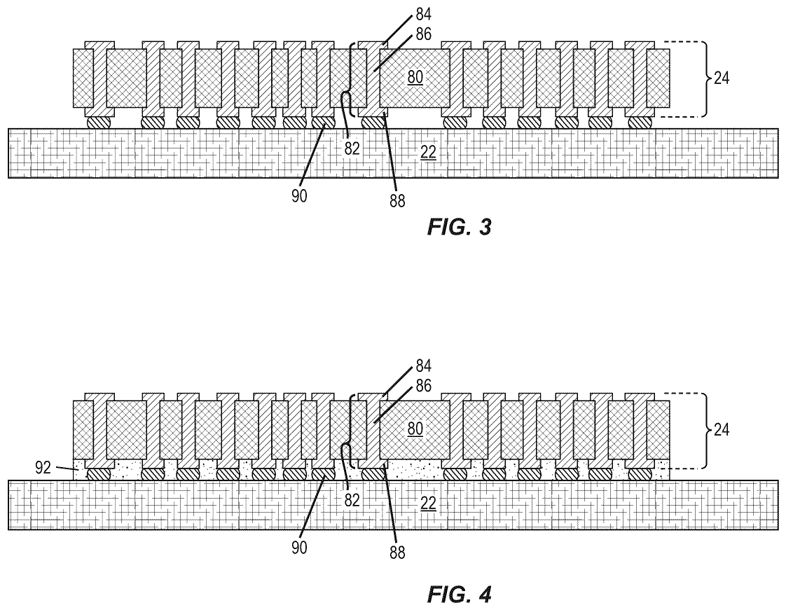

FIGS. 3-14B provide a process that illustrates exemplary steps to fabricate the RF package 10 shown in FIGS. 1A and 1B according to some embodiments of the present disclosure. Although the exemplary steps are illustrated in a series, the exemplary steps are not necessarily order dependent. Some steps may be done in a different order than that presented. Further, processes within the scope of this disclosure may include fewer or more steps than those illustrated in FIGS. 3-14B.

With reference to FIGS. 3 through 11, the shielded module 16 with the 2.5 configuration is formed according to some embodiments of the present disclosure. The interposer 24 is firstly attached to the top surface of the module substrate 22, as illustrated in FIG. 3. The interposer 24 includes the interposer body 80 and the interposer via structures 82, each of which is composed of one top via pad 84 on the top surface of the interposer body 80, one bottom via pad 88 on the bottom surface of the interposer body 80, and one TSV 86 extending through the interposer body 80 and coupled to the corresponding top and bottom via pads 84 and 88. The interposer via structures 82 are separate from each other and are formed of an electrically and thermally conductive material, such as copper.

Herein, horizontal positions of the interposer via structures 82 within the interposer body 80 correspond to configurations of the first flip-chip die 26, the first heat spreader 28, the second flip-chip die 30, and the second heat spreader 32, which are attached to the interposer 24 in the following step. In particular, horizontal positions of the interposer via structures 82 within the interposer body 80 correspond to a horizontal arrangement of the first interconnects 42 of the first flip-chip die 26, horizontal positions of the first periphery wall 52 on the first lid 50 of the first heat spreader 28, a horizontal arrangement of the second interconnects 62 of the second flip-chip die 30, and horizontal positions of the second periphery wall 72 on the second lid 70 of the second heat spreader 32.

The module substrate 22 might be composed of organic materials (e.g., FR4) and metal structures for internal connections within the organic materials (not shown) and electrical/thermal connections to external components (e.g., connection to the interposer via structures 82, not shown). The bottom via pad 88 of each interposer via structure 82 is attached to the top surface of the module substrate 22 through a corresponding solder joint 90. Next, the interposer 24 is underfilled by the underfilling material 92, as illustrated in FIG. 4. The underfilling material 92 encapsulates each solder joint 90 and each bottom via pad 88, and fills gaps between the bottom surface of the interposer body 80 of the interposer 24 and the top surface of the module substrate 22. A curing step may be followed to harden the underfilling material 92 (not shown).

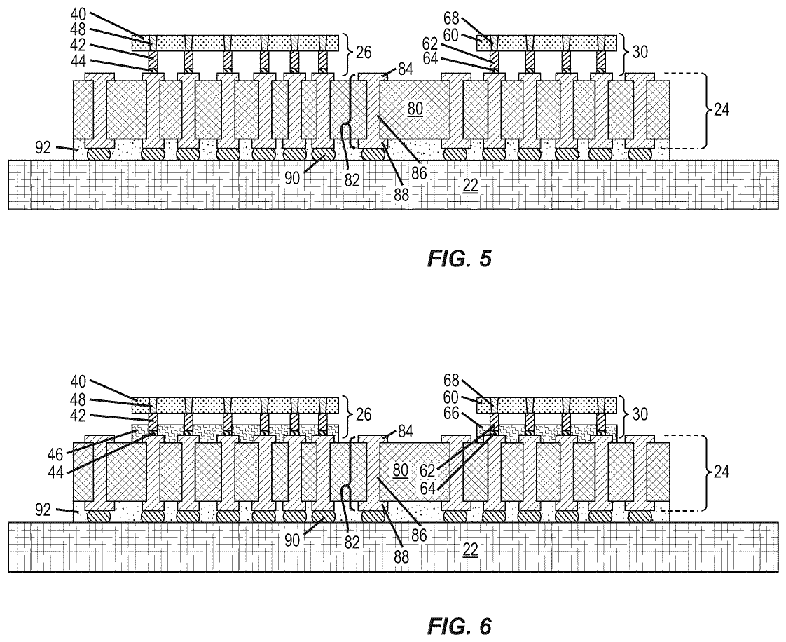

The first flip-chip die 26 and the second flip-chip die 30 are then attached to the top surface of the interposer 24, as illustrated in FIG. 5. Each of the first flip-chip die 26 and the second flip-chip die 30 may be a high-power RF die formed from GaN, GaAs, etc., or a relatively low-power die formed from silicon. The first flip-chip die 26 includes the first die body 40 and the first interconnects 42 extending outwardly from the bottom surface of the first die body 40 and is coupled to the top via pads 84 of corresponding interposer via structures 82 of the interposer 24 through the first solder caps 44, respectively. The active region (not shown) of the first flip-chip die 26 is located at the bottom portion of the first die body 40 and adjacent to the first interconnects 42. In some embodiments, the first flip-chip die 26 may also include the first die vias 48 that extend through the first die body 40 and are coupled to the corresponding first interconnects 42, respectively. As such, the heat generated in the first die body 40 can be dissipated upward to the backside of the first flip-chip die 26 through the first die vias 48, and also can be dissipated downward to the module substrate 22 through the first die vias 48, the first interconnects 42, and the corresponding interposer via structures 82 in the interposer 24.

Similarly, the second flip-chip die 30 includes the second die body 60 and the second interconnects 62 extending outwardly from the bottom surface of the second die body 60 and is coupled to the top via pads 84 of corresponding interposer via structures 82 of the interposer 24 through the second solder caps 64, respectively. The active region (not shown) of the second flip-chip die 30 is located at the bottom portion of the second die body 60 and adjacent to the second interconnects 62. In some embodiments, the second flip-chip die 30 may also include the second die vias 68 that extend through the second die body 60 and are coupled to the corresponding second interconnects 62, respectively. As such, the heat generated in the second die body 60 can be dissipated upward to the backside of the second flip-chip die 30 through the second die vias 68, and also can be dissipated downward to the module substrate 22 through the second die vias 68, the second interconnects 62, and the corresponding interposer via structures 82 in the interposer 24.

Note that, after the first flip-chip die 26 and the second flip-chip die 30 are attached to the top via pads 84 of the certain interposer via structures 82, no-attachment top via pads 84 of the remaining interposer via structures 82 are still exposed at the top surface of the interposer body 80. Some of the remaining interposer via structures 82 surround the first flip-chip die 26, while some of the other remaining interposer via structures 82 surround the second flip-chip die 30.

Next, the first protection layer 46 and the second protection layer 66 are formed over the top surface of the interposer 24 and cover the first solder caps 44 and the second solder caps 64, respectively, as illustrated in FIG. 6. In some applications, each first solder cap 44 and a small bottom portion of each first interconnect 42 are encapsulated by the first protection layer 46, while the bottom surface of the first die body 40 (where the active region of the first flip-chip die 26 is located) and the majority of each first interconnect 42 are exposed, such that the first protection layer 46 has a low impact on electrical signals propagating from or into the first flip-chip die 26. Similarly, each second solder cap 64 and a small bottom portion of each second interconnect 62 are encapsulated by the second protection layer 66, while the bottom surface of the second die body 60 (where the active region of the second flip-chip die 30 is located) and the majority of each second interconnect 62 are exposed, such that the second protection layer 66 has a low impact on electrical signals propagating from or into the second flip-chip die 30. The first protection layer 46 and the second protection layer 66 may be formed of an epoxy material. A curing step may be followed to harden the first protection layer 46 and the second protection layer 66 (not shown).

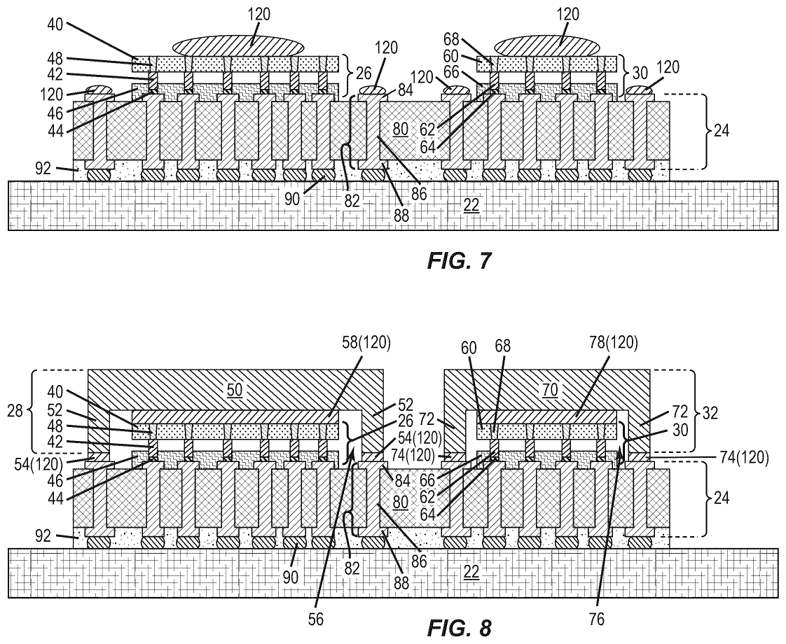

A first sintering material 120, which has a high thermal conductivity (larger than 60 W/m·K, e.g., between 60 W/m·K and 75 W/m·K), such as sintering silver or sintering copper, is then applied as illustrated in FIG. 7. The first sintering material 120 is applied to the backside of the first flip-chip die 26, the backside of the second flip-chip die 30, the exposed top via pads 84 at the top surface of the interposer body 80, and the portions of the top surface of the interposer body 80 exposed through the gaps between the exposed top via pads 84 (not shown). The first sintering material 120 may be applied by a dispensing process. The applied amount of the first sintering material 120 is determined by a curing shrinkage rate of the first sintering material 120, the height of the first flip-chip die 26, the height of the second flip-chip die 30, a height of the first periphery wall 52 of the first heat spreader 28, and a height of the second periphery wall 72 of the second heat spreader 32. For a non-limiting example, if the first flip-chip die 26 is relatively short and the first periphery wall 52 of the first heat spreader 28 is relatively tall, the amount of the first sintering material 120 applied to the backside of the first flip-chip die 26 needs to be relatively large, and the amount of the first sintering material 120 applied to certain ones of the exposed top via pads 84 surrounding the first flip-chip die 26 needs to be relatively small, so as to ensure both reliable connections between the first heat spreader 28 and the first flip-chip die 26, and between the first heat spreader 28 and the interposer 24 in the following step. In addition, if the curing shrinkage rate of the first sintering material 120 is relatively large, the applied amount of the first sintering material 120 needs to be relatively large to maintain a sufficient thickness after a curing step.

After the first sintering material 120 is applied, the first heat spreader 28 and the second heat spreader 32 are placed over the interposer 24 to cover the first flip-chip die 26 and the second flip-chip die 30, respectively, as illustrated in FIG. 8. Herein, the first heat spreader 28 includes the first lid 50 and the first periphery wall 52 extending outwardly from the periphery of the bottom surface of the first lid 50. The first lid 50 resides over the first flip-chip die 26, such that the backside of the first flip-chip die 26 is coupled to the bottom surface of the first lid 50 through the first sintering material 120, and the first periphery wall 52 surrounds the first flip-chip die 26. In addition, the first periphery wall 52 of the first heat spreader 28 is aligned with and coupled to certain ones of the exposed top via pads 84, which surround the first flip-chip die 26, through the first sintering material 120. The first air-cavity 56, within which the first flip-chip die 26 is located, is provided under the first lid 50 (i.e., between the bottom surface of the first lid 50 and the top surface of the interposer 24) and surrounded by the first periphery wall 52 (i.e., the first periphery wall 52 defines a perimeter of the first air-cavity 56). Similarly, the second heat spreader 32 includes the second lid 70 and the second periphery wall 72 extending outwardly from the periphery of the bottom surface of the second lid 70. The second lid 70 resides over the second flip-chip die 30, such that the backside of the second flip-chip die 30 is coupled to the bottom surface of the second lid 70 through the first sintering material 120, and the second periphery wall 72 surrounds the second flip-chip die 30. In addition, the second periphery wall 72 of the second heat spreader 32 is aligned with and coupled to certain ones of the exposed top via pads 84, which surround the second flip-chip die 30, through the first sintering material 120. The second air-cavity 76, within which the second flip-chip die 30 is located, is provided under the second lid 70 (i.e., between the bottom surface of the second lid 70 and the top surface of the interposer 24) and surrounded by the second periphery wall 72 (i.e., the second periphery wall 72 defines a perimeter of the second air-cavity 76).

Following the placement of the first heat spreader 28 and the second heat spreader 32, the first sintering material 120 is cured (not shown). The first sintering material 120 between the backside of the first flip-chip die 26 and the bottom surface of the first lid 50 is converted to the first sintered layer 58, and the first sintering material 120 underneath the first periphery wall 52 of the first heat spreader 28 is converted to the first sintered component 54. The first sintering material 120 between the backside of the second flip-chip die 30 and the bottom surface of the second lid 70 is converted to the second sintered layer 78, and the first sintering material 120 underneath the second periphery wall 72 of the second heat spreader 32 is converted to the second sintered component 74.

Since the applied amount of the first sintering material 120 is carefully estimated, the first heat spreader 28 is reliably connected to the first flip-chip die 26 and the interposer 24, and the second heat spreader 32 is reliably connected to the second flip-chip die 30 and the interposer 24. In addition, the first air-cavity 56 and the second air-cavity 76 are sealed, such that moisture will not enter the first/second air-cavity 56/76, which causes corrosion issue and degrades the RF performance. During the curing/sintering process, the underfilling material 92 ensures the integrity of the solder joints 90 (between the interposer 24 and the module substrate 22), the first protection layer 46 ensures the integrity of the first solder caps 44 (between the first lip-chip die 26 and the interposer 24), and the second protection layer 66 ensures the integrity of the second solder caps 64 (between the second flip-chip die 30 and the interposer 24). Without the underfilling material 92, the first protection layer 46, the second protection layer 66, the solder joints 90, the first solder caps 44, and the second solder caps 64 may be reflowed and cause electronic failure of the interposer 24, the first flip-chip die 26, and/or the second flip-chip die 30.

The heat generated in the first die body 40 of the first flip-chip die 26 can be further dissipated upward from the backside of the first flip-chip die 26 through the first sintered layer 58 toward the first lid 50 of the first heat spreader 28, and also be dissipated from the backside of the first flip-chip die 26, through the first sintered layer 58, the first lid 50 of the first heat spreader 28, the first periphery wall 52 of the first heat spreader 28, the first sintered component 54, the corresponding interposer via structures 82 (surrounding the first flip-chip die 26) of the interposer 24, toward the module substrate 22. Similarly, the heat generated in the second die body 60 of the second flip-chip die 30 can be further dissipated upward from the backside of the second flip-chip die 30 through the second sintered layer 78 toward the second lid 70 of the second heat spreader 32, and also be dissipated from the backside of the second flip-chip die 30, through the second sintered layer 78, the second lid 70 of the second heat spreader 32, the second periphery wall 72 of the second heat spreader 32, the second sintered component 74, the corresponding interposer via structures 82 (surrounding the second flip-chip die 30) of the interposer 24, toward the module substrate 22. Besides the thermal dissipation, the first periphery wall 52 of the first heat spreader 28 and the second periphery wall 72 of the second heat spreader 32 are further configured to provide structural or mechanical support for the oversized first lid 50 of the first heat spreader 26 and the second lid 70 of the second heat spreader 32, respectively, during the placement and curing process.

Note that each interposer via structure 82 is coupled to and aligned with one of the first interconnects 42 of the first flip-chip die 26, the first periphery wall 52 of the first heat spreader 28, one of the second interconnects 62 of the second flip-chip die 30, or the second periphery wall 72 of the second heat spreader 32. Herein, the interposer via structures 82 vertically between the first flip-chip die 26/the second flip-chip die 30 and the module substrate 22 are configured to transmit both electrical signals and provide a thermal path, while the interposer via structures 82 vertically between the first periphery wall 52/the second periphery wall 72 and the module substrate 22 are configured to only dissipate heat.

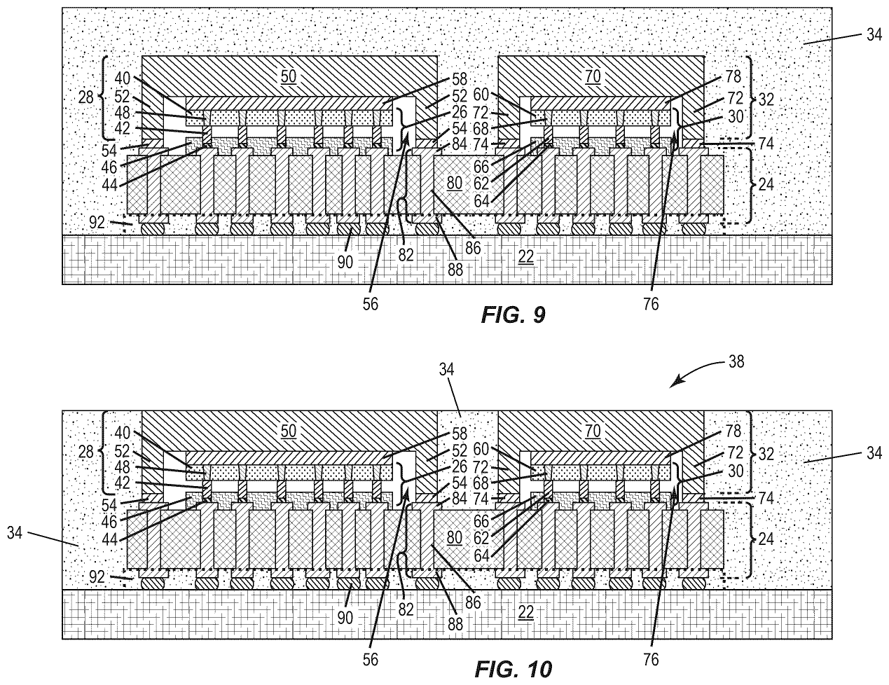

Next, the mold compound 34 is applied over the top surface of the module substrate 22 to encapsulate the interposer 24, the first spreader 28, and the second spreader 32, as illustrated in FIG. 9. The mold compound 34 does not fill the first air-cavity 56 or the second air-cavity 76 and is not in contact with the first flip-chip die 26 or the second flip-chip die 30. The mold compound 34 may be applied by a compression molding, or the like. The underfilling material 92 (between the bottom surface of the interposer 24 and the top surface of the module substrate 22), the first protection layer 46, the second protection layer 66, and the mold compound 34 may be formed from a same material, such as epoxy. During this molding step, the first periphery wall 52 of the first heat spreader 28 and the second periphery fence 72 of the second heat spreader 32 may provide structural/mechanical support for the oversized first heat spreader 28 and the oversized second periphery fence 32, respectively, and may also mitigate deformation risk of the first flip-chip die 26 and the second flip-chip die 30. A curing step may be followed to harden the mold compound 34 (not shown).

The mold compound 34 is then thinned down to expose both the top surface of the first heat spreader 28 (i.e., the top surface of the first lid 50) and the top surface of the second heat spreader 32 (i.e., the top surface of the second lid 70), and to provide the electronic module 38, as illustrated in FIG. 10. The thinning procedure may be done with a mechanical grinding process. After the thinning procedure, the top surface of the first heat spreader 28, the top surface of the second heat spreader 32, and the top surface of the mold compound 34 are coplanar and constitute the top surface of the electronic module 38. The side surface of the electronic module 38 is a combination of the side surface of the mold compound 34 and the side surface of the module substrate 22, and the bottom surface of the electronic module 38 is the bottom surface of the module substrate 22.

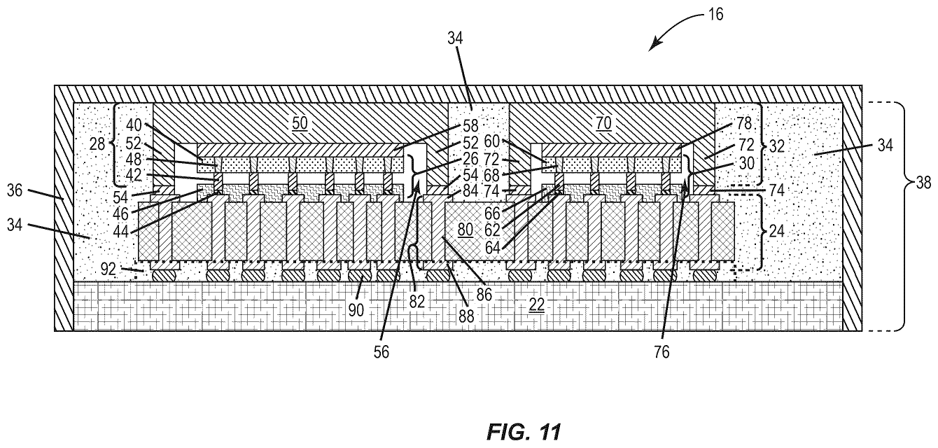

The shielding structure 36 is applied to the electronic module 38 to complete the shielded module 16, as illustrated in FIG. 11. The shielding structure 36 directly and completely covers the top surface of the electronic module 38 and directly covers at least a majority of the side surface of the electronic module 38, while a bottom surface of the electronic module 38 is exposed. In some applications, the shielding structure 36 may completely cover the side surface of the electronic module 38, while in some applications, the shielding structure 36 may only cover the side surface of the mold compound 34, leaving the side surface of the module substrate 22 exposed (not shown). Since the top surface of the electronic module 38 includes the top surface of the first heat spreader 28 and the top of the second heat spreader 32, the shielding structure 36 is physically and thermally connected to both the first heat spreader 28 and the second heat spreader 32. In addition, the shielding structure 36 is formed from conductive materials (as described above). Therefore, the heat dissipated upward can pass through the shielding structure 36.

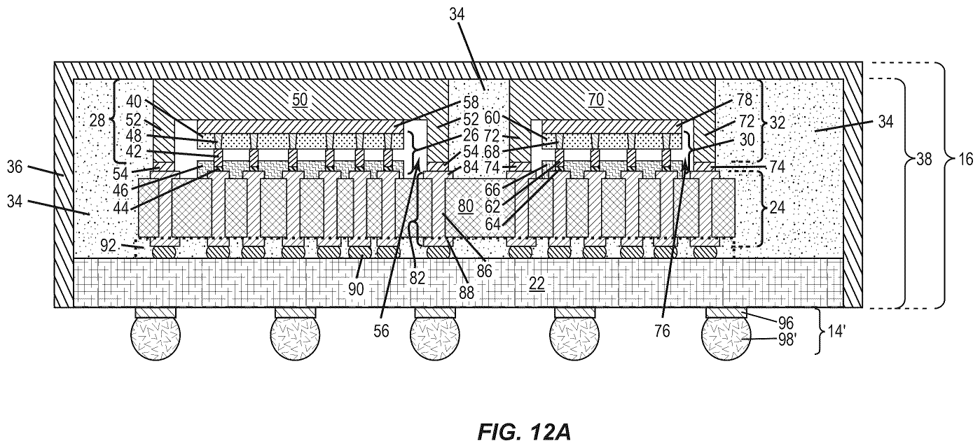

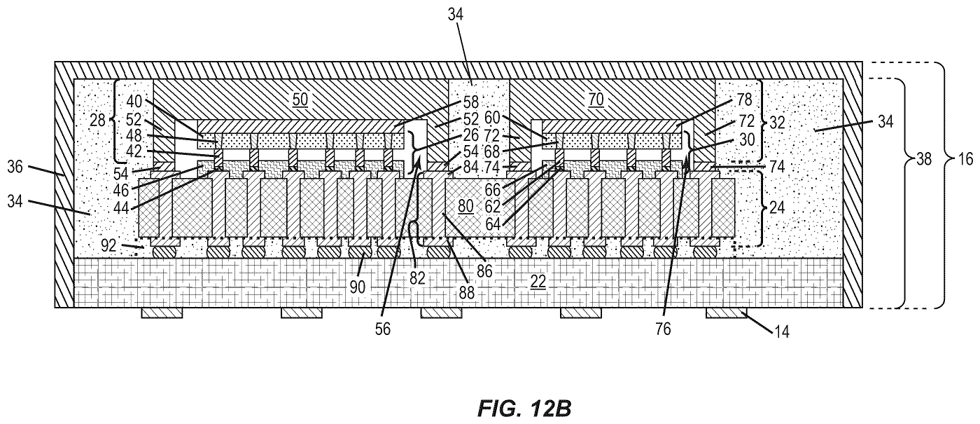

In some embodiments, the BGA technology is used for further attachment of the shielded module 16. As shown in FIG. 12A, initial electrical contacts 14′, each of which includes one substrate pad 96 and an initial solder ball 98′, are formed at a bottom surface of the shielded module 16 (i.e., the bottom surface of the module substrate 22). Each initial electrical contact 14′ is connected to the metal structures within the module substrate 22 (not shown). In some embodiments, the LGA technology is used for further attachment of the shielded module 16. As shown in FIG. 12B, the electrical contacts 14, each of which is one plated metal pad, are formed at the bottom surface of the shielded module 16. Each electrical contact 14 is also connected to the metal structures within the module substrate 22 (not shown).

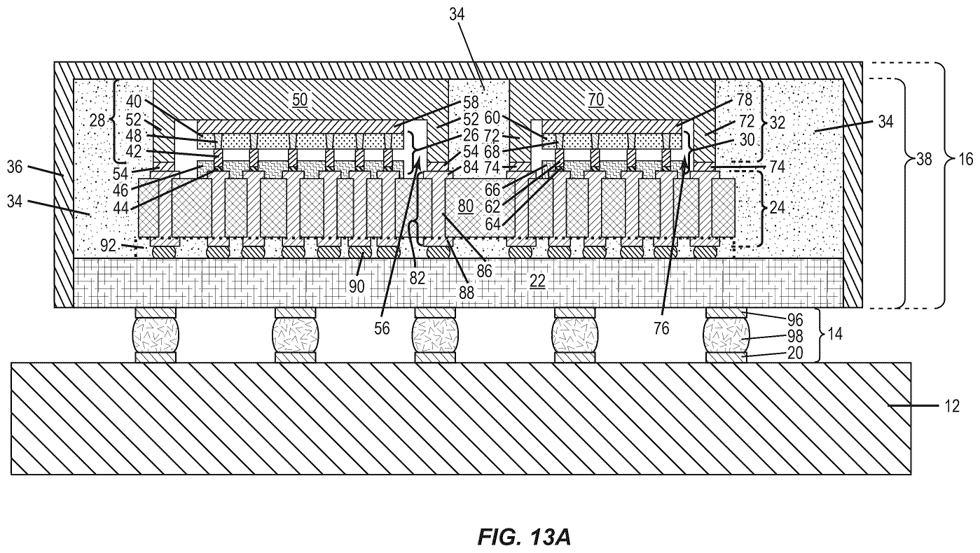

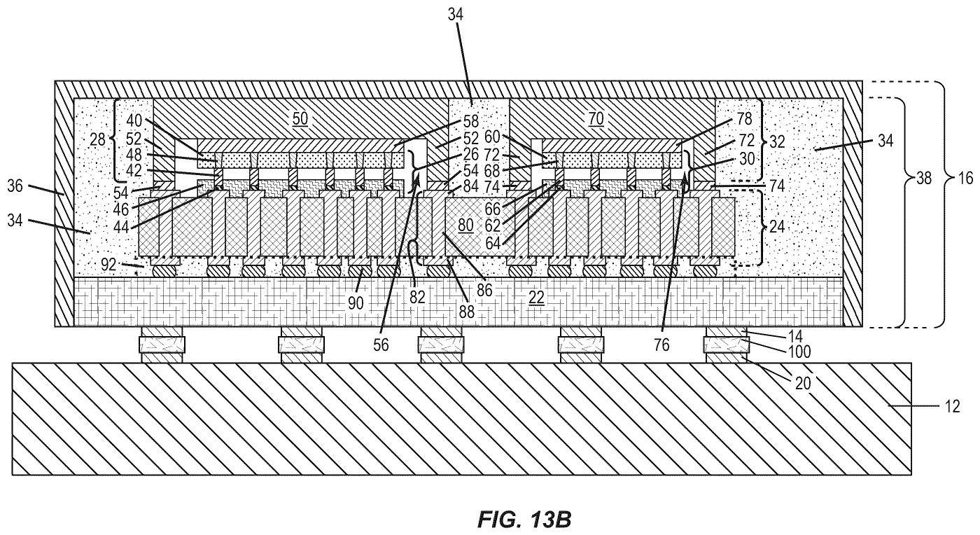

Next, the shielded module 16 is attached to the carrier board 12, as illustrated in FIGS. 13A and 13B. For the case of the BGA technology, each initial solder ball 98′ reflows and is in contact with a corresponding carrier connector 20 on the top surface of the carrier board 12 (FIG. 13A). Each initial solder ball 98′ is converted to the reflowed solder ball 98, and each initial electrical contact 14′ is converted to the electrical contact 14. For the case of the LGA technology, each electrical contact 14 (each plated metal pad) is connected to a corresponding carrier connector 20 via the solder paste 100 (FIG. 13B). Regardless of whether the BGA or LGA is used, the heat generated from the first flip-chip die 26 and the second flip-chip die 30 within the shielded module 16 can be further dissipated downwards to the carrier board 12 through the module substrate 22 and the electrical contacts 14.

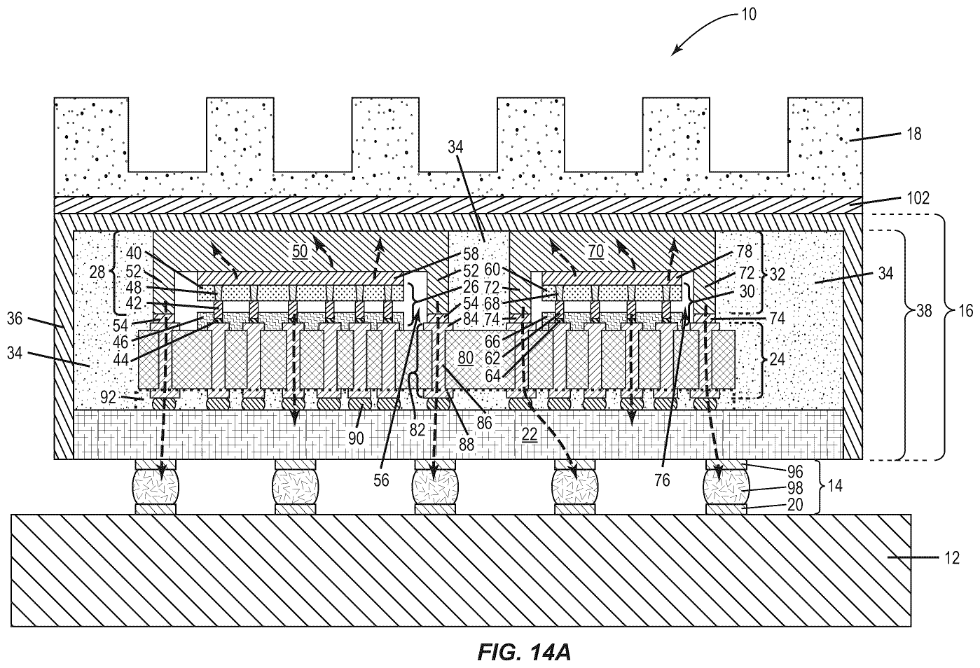

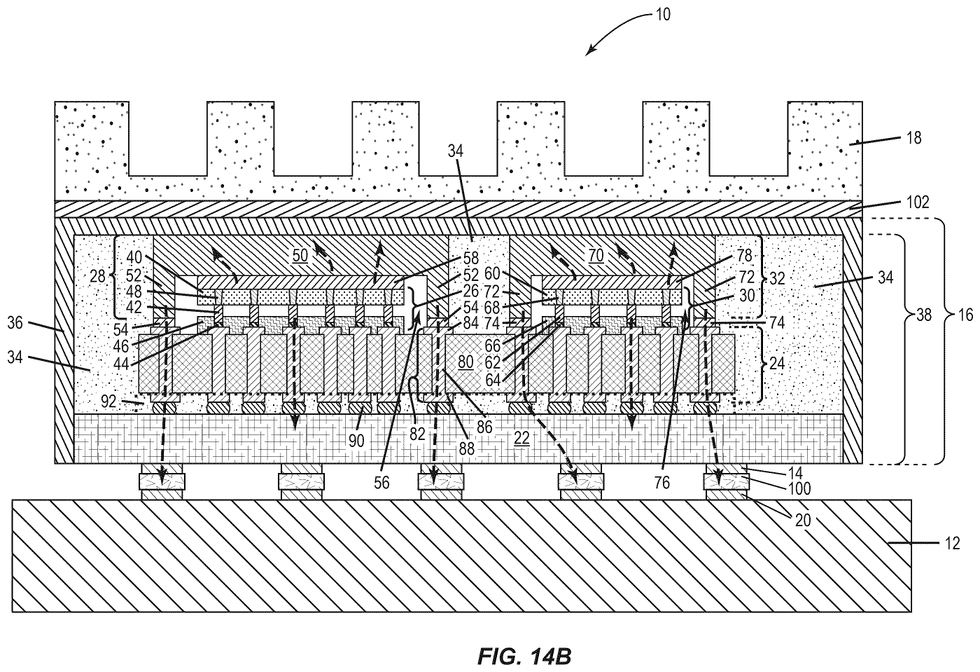

Lastly, the heat sink 18 may be attached to the top surface of the shielded module 16 via the adhesion layer 102, as illustrated in FIGS. 14A and 14B. Herein, the first heat spreader 28 and the second heat spreader 32 are thermally connected to the heat sink 18 through the shielding structure 36 and the adhesion layer 102. As such, the heat generated from the first flip-chip die 26 and the second flip-chip die 30 within the shielded module 16 can be further dissipated upwards to the heat sink 18.

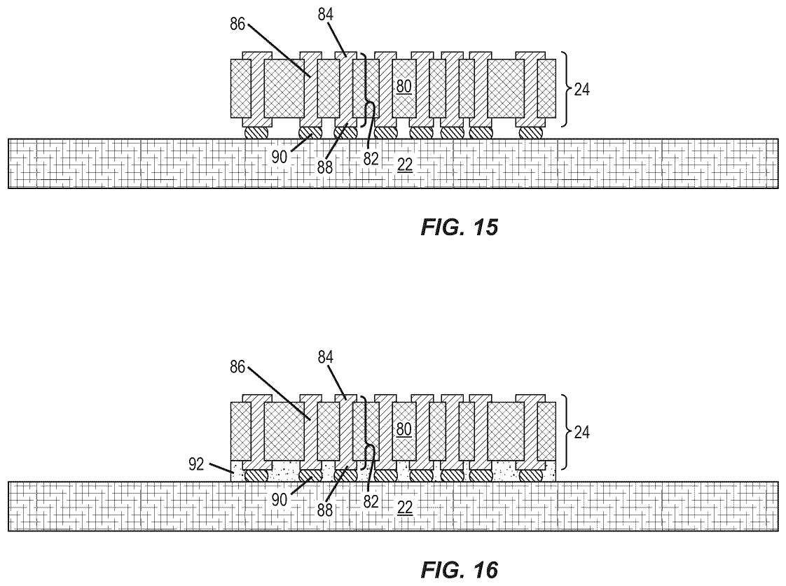

FIGS. 15-28B provide an alternative process that illustrates steps to fabricate the RF package 10 shown in FIGS. 2A and 2B according to some embodiments of the present disclosure. Although the exemplary steps are illustrated in a series, the exemplary steps are not necessarily order dependent. Some steps may be done in a different order than that presented. Further, processes within the scope of this disclosure may include fewer or more steps than those illustrated in FIGS. 15-28B.

With reference to FIGS. 15 through 25, the shielded module 16 with the 3D configuration is formed according to some embodiments of the present disclosure. The interposer 24 is firstly attached to the top surface of the module substrate 22, as illustrated in FIG. 15. The interposer 24 includes the interposer body 80 and the interposer via structures 82, each of which is composed of one top via pad 84 on the top surface of the interposer body 80, one bottom via pad 88 on the bottom surface of the interposer body 80, and one TSV 86 extending through the interposer body 80 and coupled to the corresponding top and bottom via pads 84 and 88. The interposer via structures 82 are separate from each other and are formed of an electrically and thermally conductive material, such as copper. Herein, horizontal positions of the interposer via structures 82 within the interposer body 80 correspond to configurations of the first flip-chip die 26 and the first heat spreader 28, which are attached to the interposer 24 in the following step. In particular, horizontal positions of the interposer via structures 82 within the interposer body 80 correspond to the horizontal arrangement of the first interconnects 42 of the first flip-chip die 26 and the horizontal positions of the first periphery wall 52 on the first lid 50 of the first heat spreader 28.

The module substrate 22 might be composed of organic materials (e.g., FR4) and metal structures for internal connections within the organic materials (not shown) and electrical/thermal connections to external components (e.g., connection to the interposer via structures 82, not shown). The bottom via pad 88 of each interposer via structure 82 is attached to the top surface of the module substrate 22 through the corresponding solder joint 90. Next, the interposer 24 is underfilled by the underfilling material 92, as illustrated in FIG. 16. The underfilling material 92 encapsulates each solder joint 90 and each bottom via pad 88 and fills gaps between the bottom surface of the interposer body 80 of the interposer 24 and the top surface of the module substrate 22. A curing step may be followed to harden the underfilling material 92 (not shown).

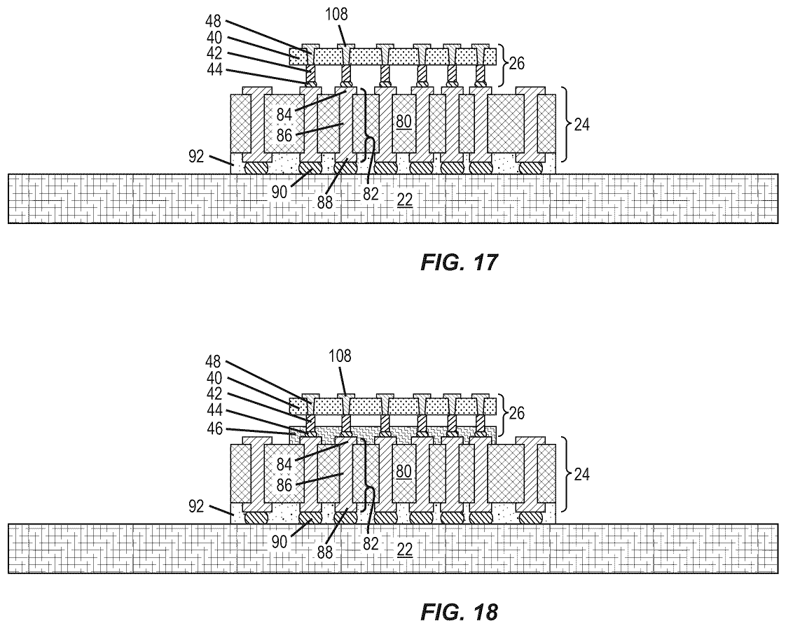

The first flip-chip die 26 is then attached to the top surface of the interposer 24, as illustrated in FIG. 17. The first flip-chip die 26 may be a high-power RF die formed from GaN, GaAs, etc., or a relatively low-power die formed from silicon. The first flip-chip die 26 includes the first die body 40 and the first interconnects 42 extending outwardly from the bottom surface of the first die body 40 and is coupled to the top via pads 84 of corresponding interposer via structures 82 of the interposer 24 through the first solder caps 44, respectively. The active region (not shown) of the first flip-chip die 26 is located at the bottom portion of the first die body 40 and adjacent to the first interconnects 42. In some embodiments, the first flip-chip die 26 may also include the first die vias 48 that extend through the first die body 40 and are coupled to the corresponding first interconnects 42, respectively. As such, the heat generated in the first die body 40 can be dissipated upward to the backside of the first flip-chip die 26 through the first die vias 48, and also can be dissipated downward to the module substrate 22 through the first die vias 48, the first interconnects 42, and the corresponding interposer via structures 82 in the interposer 24. Note that, after the first flip-chip die 26 is attached to the top via pads 84 of the certain interposer via structures 82, no-attachment top via pads 84 of the remaining interposer via structures 82 are still exposed at the top surface of the interposer body 80. These remaining interposer via structures 82 surround the first flip-chip die 26.

In order to accommodate the extra flip-chip die 106 in a following step, the first flip-chip die 26 may further include the die via pads 108 on the backside of the first flip-chip die 26 (i.e., the top surface of the first die body 40 of the first flip-chip die 26). The die via pads 108 may be formed by selectively etching a plated metal film on the backside of the first flip-chip die 26. The number and location of the die via pads 108 on the backside of the first flip-chip die 26 correspond to the number and horizontal arrangement of the interconnects 112 of the extra flip-chip die 106, which are attached to the die via pads 108.

Next, the first protection layer 46 is formed over the top surface of the interposer 24 and covers the first solder caps 44, as illustrated in FIG. 18. In some applications, each first solder cap 44 and a small bottom portion of each first interconnect 42 are encapsulated by the first protection layer 46, while the bottom surface of the first die body 40 (where the active region of the first flip-chip die 26 is located) and the majority of each first interconnect 42 are exposed, such that the first protection layer 46 has a low impact on electrical signals propagating from or into the first flip-chip die 26. The first protection layer 46 may be formed of an epoxy material. A curing step may be followed to harden the first protection layer 46 (not shown).

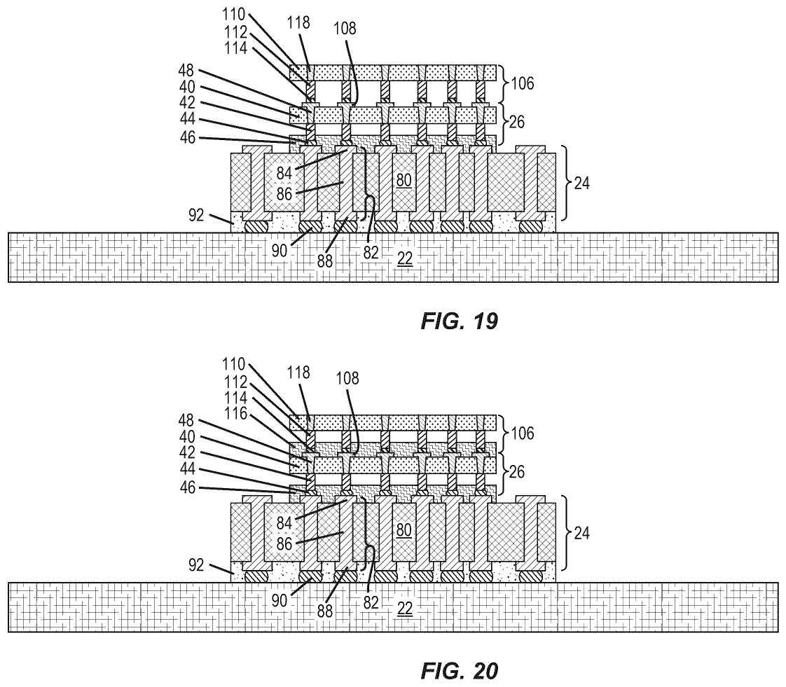

The extra flip-chip die 106 is then attached to the backside of the first flip-chip die 26, as illustrated in FIG. 19. The extra flip-chip die 106 includes the die body 110 and the interconnects 112 that extend outwardly from the bottom surface of the die body 110 and are coupled to the backside of the first flip-chip die 26. An active region (not shown) of the extra flip-chip die 106 is located at the bottom portion of the die body 110 and adjacent to the interconnects 112. In detail, the die body 110 of the extra flip-chip die 106 may be formed from GaN with SiC, GaAs with SiC, silicon, or any appropriate semiconductor material(s), and each interconnect 112 may be a copper pillar and is coupled to a corresponding die via pad 108 via one solder cap 114. In one embodiment, each die via pad 108 is directly formed over a corresponding first die via 48 within the first die body 40 of the first flip-chip die 26 and is aligned with and coupled to a corresponding interconnect 112 of the extra flip-chip die 106.

In some embodiments, the extra flip-chip die 106 includes the die vias 118 extending through the die body 110 and coupled to corresponding interconnects 112, respectively. The die vias 118 are configured to dissipate heat generated in the die body 110 of the extra flip-chip die 106 towards the backside of the extra flip-chip die 106, which enables top-side cooling of the extra flip-chip die 106, and towards the interconnects 112 of the extra flip-chip die 106, which enables down-side cooling of the extra flip-chip die 106. As such, the heat generated in the first die body 40 can be dissipated further upward through the extra flip-chip die 106 (e.g., from the die via pads 108 at the backside of the first flip-chip die 26, through the solder caps 114, the interconnects 112 of the extra flip-chip die 106, and the die vias 118 extending through the die body 110 of the extra flip-chip die 106). In addition, the heat generated in the extra flip-chip die 106 can be dissipated further downward to the module substrate 22 through the first flip-chip die 26 (e.g., from the interconnects 112 of the extra flip-chip die 106, through the solder caps 114, the die via pads 108 at the backside of the first flip-chip die 26, the first die vias 48 extending to the first die body 40, the first interconnects 42, and the first solder caps 44) and the corresponding interposer via structures 82 of the interposer 24.

After the extra flip-chip die 106 is attached to the backside of the first flip-chip die 26, the extra protection layer 116 is formed on the backside of the first flip-chip die 26 and covers the solder caps 114, as illustrated in FIG. 20. In some applications, each solder cap 114 and a small bottom portion of each interconnect 112 of the extra flip-chip die 106 are encapsulated by the extra protection layer 106, while the bottom surface of the die body 40 of the extra flip-chip die 106 (where the active region of the extra flip-chip die 106 is located) and the majority of each interconnect 112 of the extra flip-chip die 106 are exposed, such that the extra protection layer 116 has a low impact on electrical signals propagating from or into the extra flip-chip die 106. The extra protection layer 116 may be formed of an epoxy material. A curing step may be followed to harden the extra protection layer 116 (not shown).

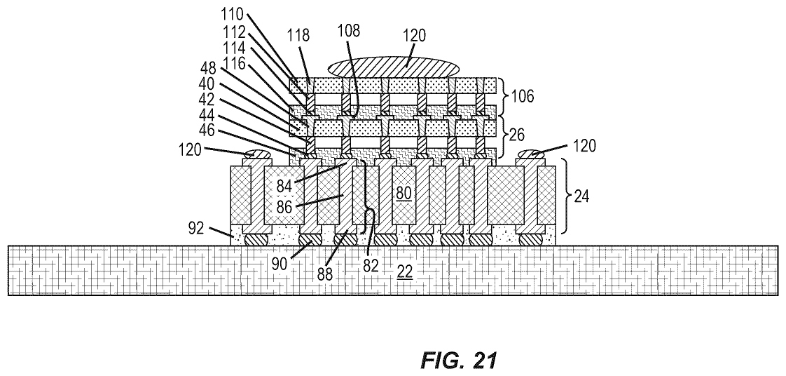

The first sintering material 120, which has a high thermal conductivity (larger than 60 W/m·K, e.g., between 60 W/m·K and 75 W/m·K), such as sintering silver or sintering copper, is then applied as illustrated in FIG. 21. The first sintering material 120 is applied to the backside of the extra flip-chip die 106, the exposed top via pads 84 at the top surface of the interposer body 80, and the portions of the top surface of the interposer body 80 exposed through the gaps between the exposed top via pads 84 (not shown). The first sintering material 120 may be applied by a dispensing process. The applied amount of the first sintering material 120 is determined by a curing shrinkage rate of the first sintering material 120, a combined height of the first flip-chip die 26 and the extra flip-chip die 106, and a height of the first periphery wall 52 of the first heat spreader 28. For a non-limiting example, if the combined height of the first flip-chip die 26 and the extra flip-chip die 106 is relatively short and the first periphery wall 52 of the first heat spreader 28 is relatively tall, the amount of the first sintering material 120 applied to the backside of the extra flip-chip die 106 needs to be relatively large, and the amount of the first sintering material 120 applied to the exposed top via pads 84 needs to be relatively small, so as to ensure both reliable connections between the first heat spreader 28 and the extra flip-chip die 106, and between the first heat spreader 28 and the interposer 24 in the following step. In addition, if the curing shrinkage rate of the first sintering material 120 is relatively large, the applied amount of the first sintering material 120 needs to be relatively large to maintain a sufficient thickness after a curing step.

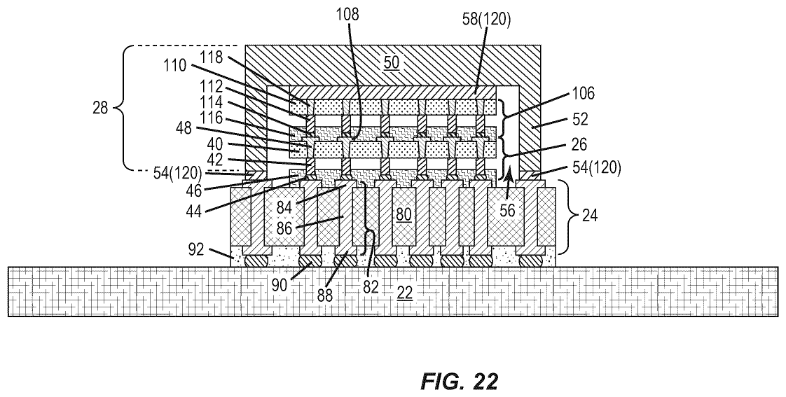

After the first sintering material 120 is applied, the first heat spreader 28 is placed over the interposer 24 to cover the combination of the first flip-chip die 26 and the second flip-chip die 30, as illustrated in FIG. 22. Herein, the first heat spreader 28 includes the first lid 50 and the first periphery wall 52 extending outwardly from the periphery of the bottom surface of the first lid 50. The first lid 50 resides over the extra flip-chip die 106, such that the backside of the extra flip-chip die 106 is coupled to the bottom surface of the first lid 50 through the first sintering material 120, and the first periphery wall 52 surrounds the combination of the first flip-chip die 26 and the second flip-chip die 30. In addition, the first periphery wall 52 of the first heat spreader 28 is aligned with and coupled to the exposed top via pads 84 of corresponding interposer via structures 82, which surround the combination of the first flip-chip die 26 and the second flip-chip die 30, through the first sintering material 120. The first air-cavity 56, within which the combination of the first flip-chip die 26 and the second flip-chip die 30 is located, is provided under the first lid 50 (i.e., between the bottom surface of the first lid 50 and the top surface of the interposer 24) and surrounded by the first periphery wall 52 (i.e., the first periphery wall 52 defines a perimeter of the first air-cavity 56).

Following the placement of the first heat spreader 28, the first sintering material 120 is cured (not shown). The first sintering material 120 between the backside of the extra flip-chip die 106 and the bottom surface of the first lid 50 is converted to the first sintered layer 58, and the first sintering material 120 underneath the first periphery wall 52 of the first heat spreader 28 is converted to the first sintered component 54. Since the applied amount of the first sintering material 120 is carefully estimated, the first heat spreader 28 is reliably connected to the extra flip-chip die 106 and the interposer 24, and the first air-cavity 56 is sealed. During the curing/sintering process, the underfilling material 92 ensures the integrity of the solder joints 90 (between the interposer 24 and the module substrate 22), the first protection layer 46 ensures the integrity of the first solder caps 44 (between the first flip-chip die 26 and the interposer 24), and the extra protection layer 116 ensures the integrity of the solder caps 114 (between the extra flip-chip die 106 and the first flip-chip die 26). Without the underfilling material 92, the first protection layer 46, and the extra protection layer 116, the solder joints 90, the first solder caps 44, and the solder caps 114 may be reflowed and cause electronic failure of the interposer 24, the first flip-chip die 26, and/or the extra flip-chip die 116.

The heat generated in the extra flip-chip die 106 and in the first flip-chip die 26 can be further dissipated upward from the backside of the extra flip-chip die 106 through the first sintered layer 58 toward the first lid 50 of the first heat spreader 28, and also be dissipated from the backside of the extra flip-chip die 106, through the first sintered layer 58, the first lid 50 of the first heat spreader 28, the first periphery wall 52 of the first heat spreader 28, the first sintered component 54, the corresponding interposer via structures 82 of the interposer 24, toward the module substrate 22. Besides the thermal dissipation, the first periphery wall 52 of the first heat spreader 28 is further configured to provide structural or mechanical support for the oversized first lid 50 of the first heat spreader 26 during the placement and curing process. Each interposer via structure 82 is coupled to and aligned with one of the first interconnects 42 of the first flip-chip die 26 and the first periphery wall 52 of the first heat spreader 28. Herein, the interposer via structures 82 vertically between the first flip-chip die 26 and the module substrate 22 are configured to transmit both electrical signals and provide a thermal path, while the interposer via structures 82 vertically between the first periphery wall 52 and the module substrate 22 are configured to only dissipate heat.

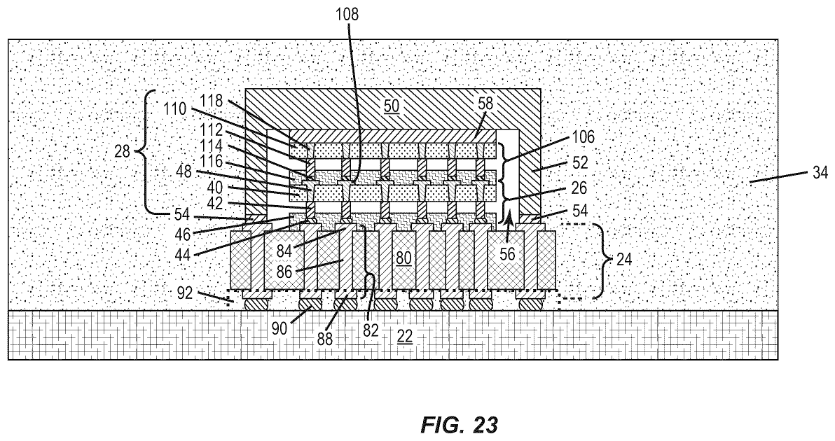

Next, the mold compound 34 is applied over the top surface of the module substrate 22 to encapsulate the interposer 24 and the first spreader 28, as illustrated in FIG. 23. The mold compound 34 does not fill the first air-cavity 56 and is not in contact with the first flip-chip die 26 or the extra flip-chip die 106. The mold compound 34 may be applied by a compression molding, or the like. The underfilling material 92, the first protection layer 46, the extra protection layer 106, and the mold compound 34 may be formed from a same material, such as epoxy. During this molding step, the first periphery wall 52 of the first heat spreader 28 may provide structural/mechanical support for the oversized first heat spreader 28, and may also mitigate deformation risk of the first flip-chip die 26 and the extra flip-chip die 106. A curing step may be followed to harden the mold compound 34 (not shown).

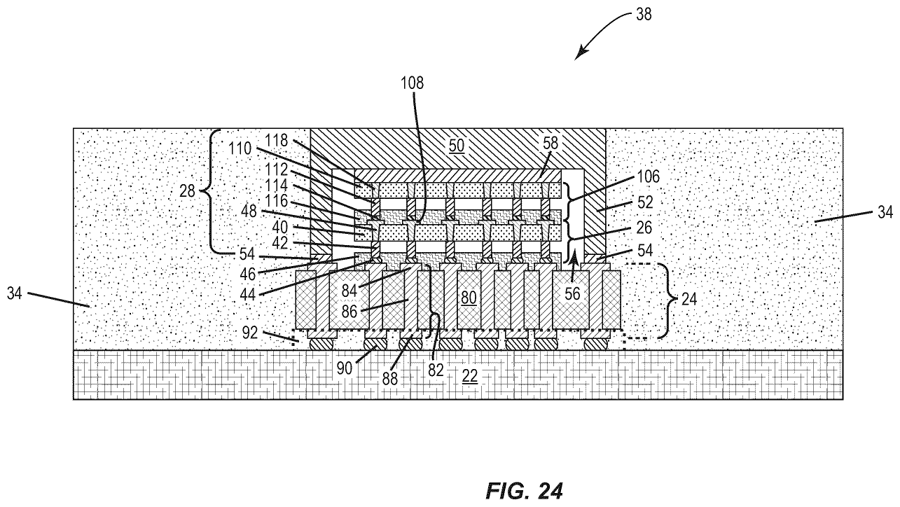

The mold compound 34 is then thinned down to expose the top surface of the first heat spreader 28 (i.e., the top surface of the first lid 50) and to provide the electronic module 38, as illustrated in FIG. 24. The thinning procedure may be done with a mechanical grinding process. After the thinning procedure, the top surface of the first heat spreader 28 and the top surface of the mold compound 34 are coplanar and constitute the top surface of the electronic module 38. The side surface of the electronic module 38 is a combination of the side surface of the mold compound 34 and the side surface of the module substrate 22, and the bottom surface of the electronic module 38 is the bottom surface of the module substrate 22.

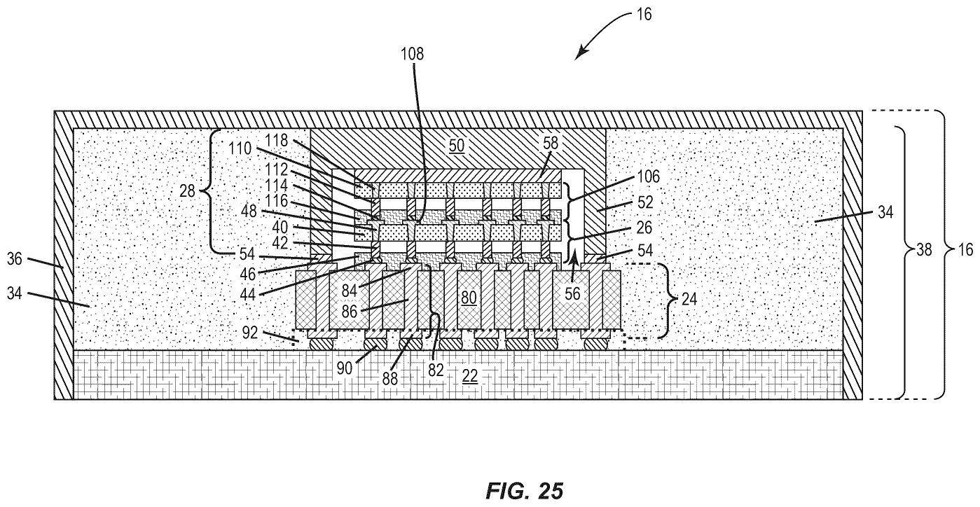

The shielding structure 36 is applied to the electronic module 38 to complete the shielded module 16, as illustrated in FIG. 25. The shielding structure 36 directly and completely covers the top surface of the electronic module 38 and directly covers at least a majority of the side surface of the electronic module 38, while a bottom surface of the electronic module 38 is exposed. In some applications, the shielding structure 36 may completely cover the side surface of the electronic module 38, while in some applications, the shielding structure 36 may only cover the side surface of the mold compound 34, leaving the side surface of the module substrate 22 exposed (not shown). Since the top surface of the electronic module 38 includes the top surface of the first heat spreader 28, the shielding structure 36 is physically and thermally connected to the first heat spreader 28. In addition, the shielding structure 36 is formed from conductive materials (as described above). Therefore, the heat dissipated upward can pass through the shielding structure 36.

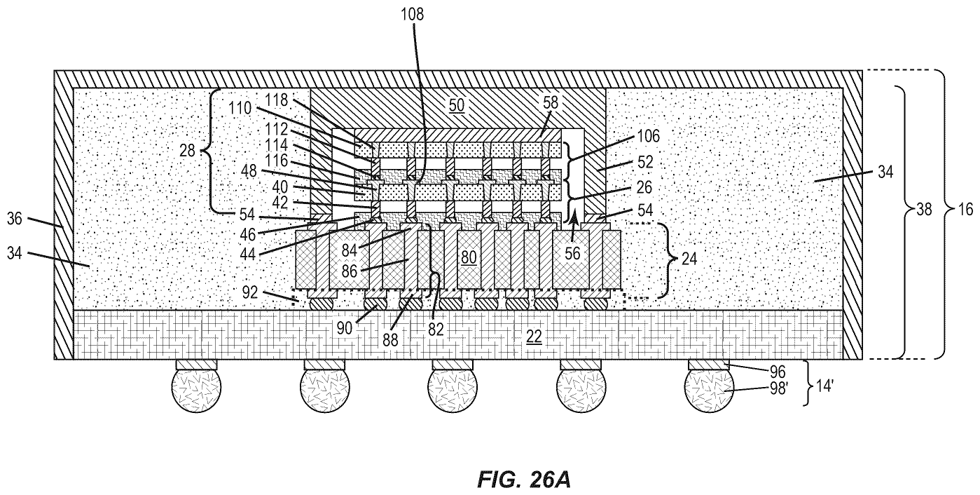

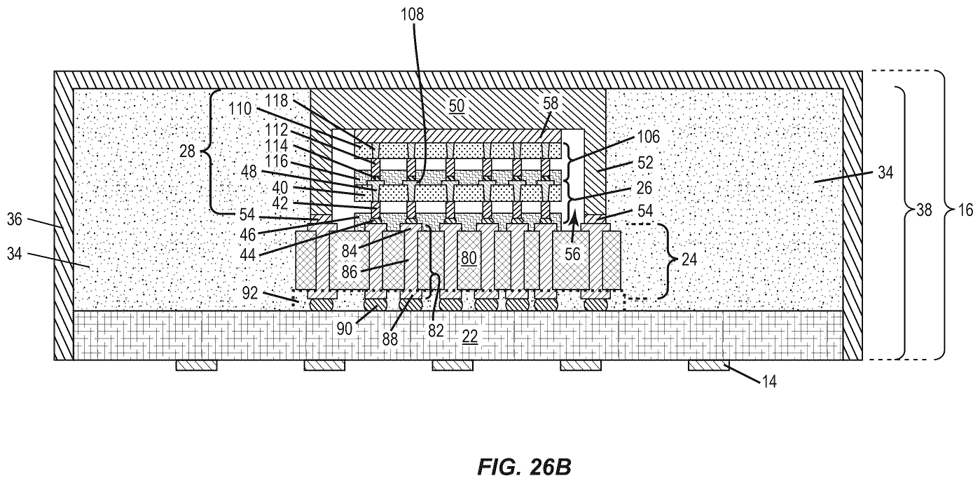

In some embodiments, the BGA technology is used for further attachment of the shielded module 16. As shown in FIG. 26A, initial electrical contacts 14′, each of which includes one substrate pad 96 and one initial solder ball 98′, are formed at a bottom surface of the shielded module 16 (i.e., the bottom surface of the module substrate 22). Each initial electrical contacts 14′ is connected to the metal structures within the module substrate 22 (not shown). In some embodiments, the LGA technology is used for further attachment of the shielded module 16. As shown in FIG. 26B, the electrical contacts 14, each of which is one plated metal pad, are formed at the bottom surface of the shielded module 16. Each electrical contact 14 is also connected to the metal structures within the module substrate 22 (not shown).

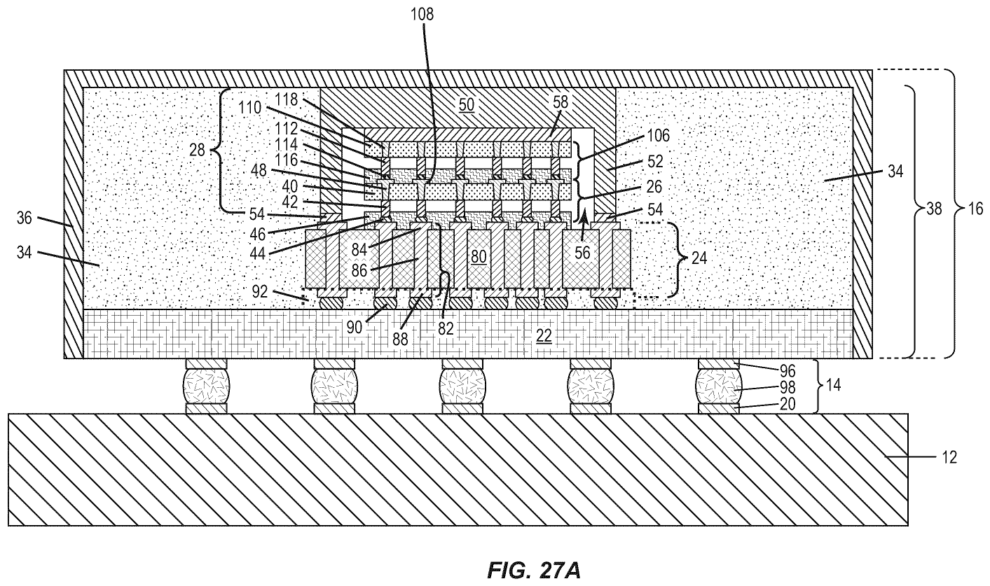

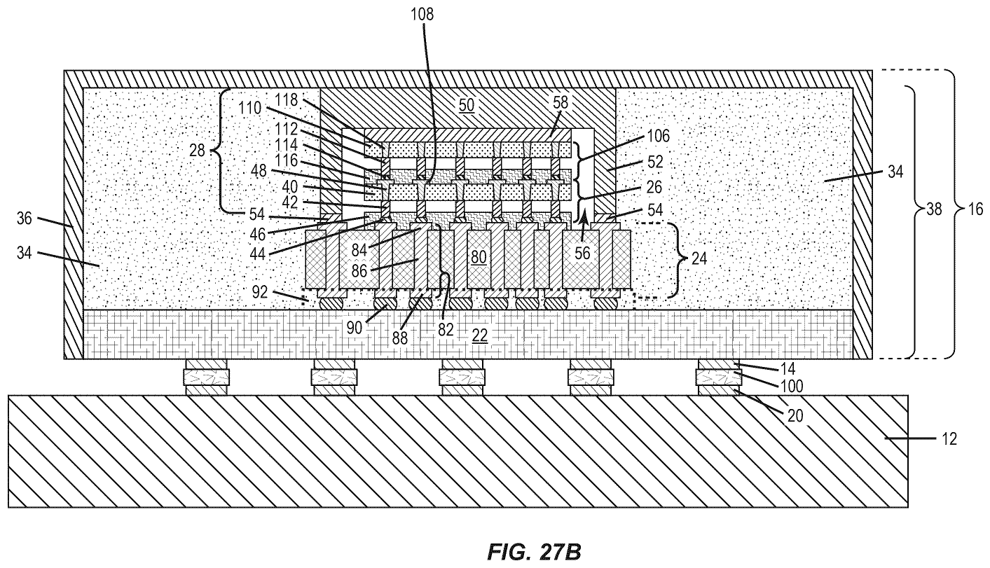

Next, the shielded module 16 is attached to the carrier board 12, as illustrated in FIGS. 27A and 27B. For the case of the BGA technology, each initial solder ball 98′ reflows and is in contact with a corresponding carrier connector 20 on the top surface of the carrier board 12 (FIG. 27A). Each initial solder ball 98′ is converted to the reflowed solder ball 98, and each initial electrical contact 14′ is converted to the electrical contact 14. For the case of the LGA technology, each electrical contact 14 (each plated metal pad) is connected to a corresponding carrier connector 20 via the solder paste 100 (FIG. 27B). Regardless of whether the BGA or LGA is used, the heat generated from the first flip-chip die 26 and the extra flip-chip die 106 within the shielded module 16 can be further dissipated downwards to the carrier board 12 through the module substrate 22 and the electrical contacts 14.

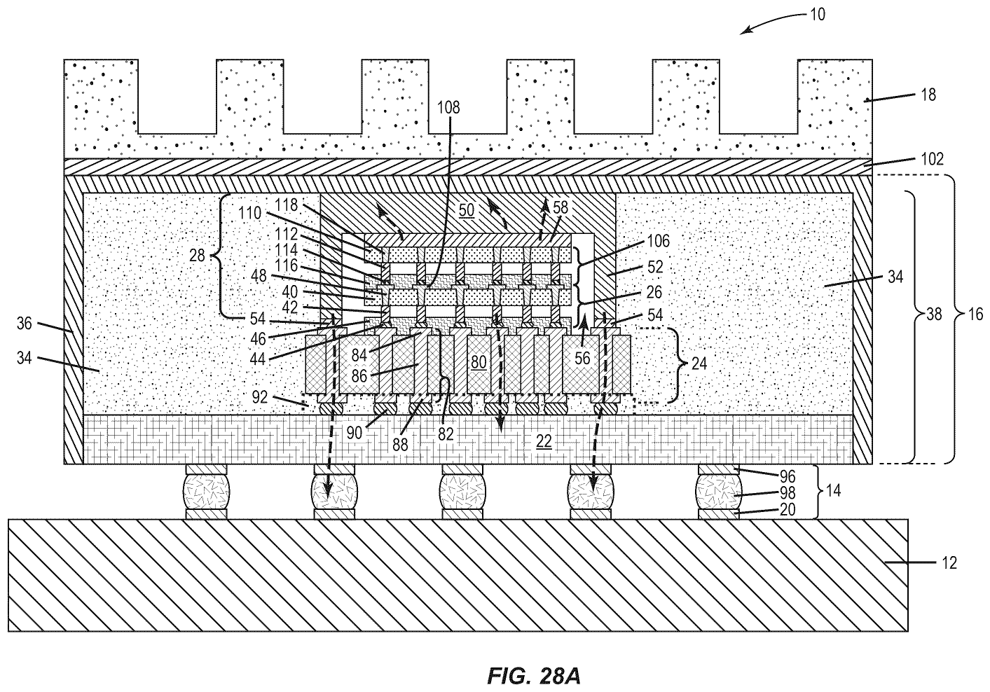

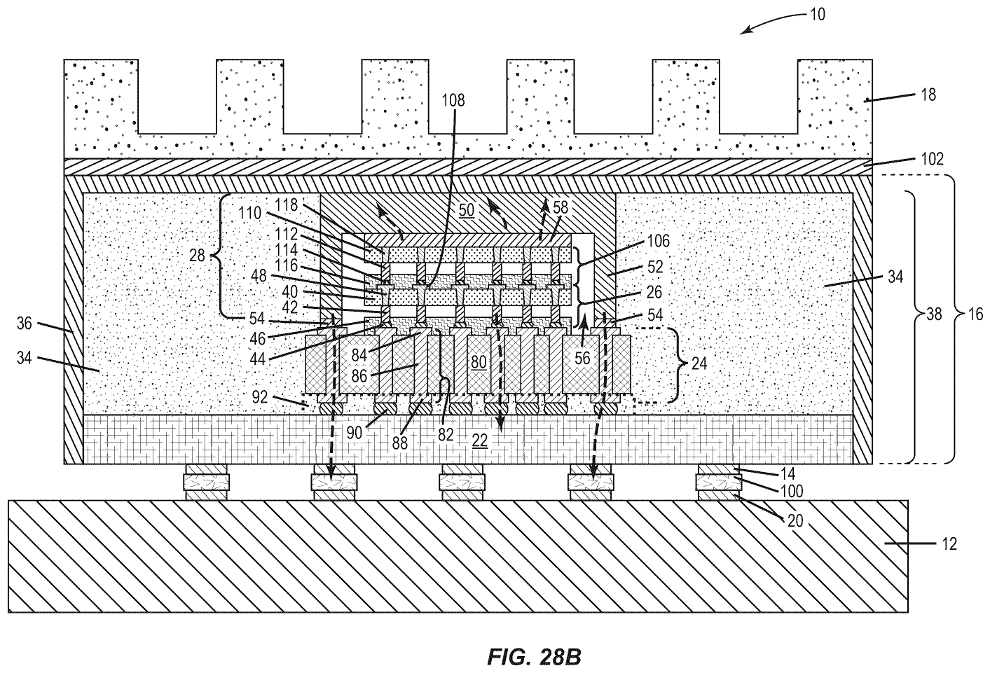

Lastly, the heat sink 18 may be attached to the top surface of the shielded module 16 via the adhesion layer 102, as illustrated in FIGS. 28A and 28B. Herein, the first heat spreader 28 and the second heat spreader 32 are thermally connected to the heat sink 18 through the shielding structure 36 and the adhesion layer 102. As such, the heat generated from the extra flip-chip die 106 and the first flip-chip die 26 within the shielded module 16 can be further dissipated upwards to the heat sink 18.

The systems and methods for efficient heat dissipation and superior electrical performance of an RF package, according to aspects disclosed herein, may be provided in or integrated into any high-power RF processor-based electronics. Examples, without limitation, include a base station, a military application device, a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

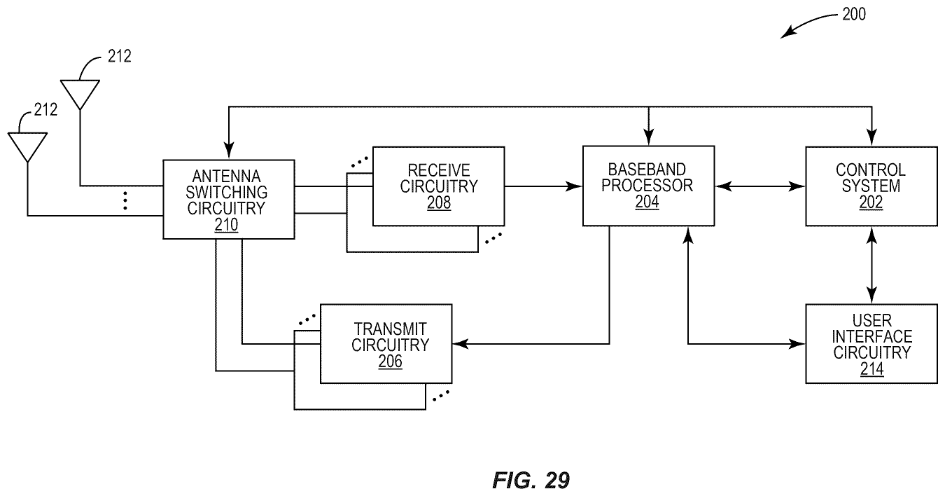

With reference to FIG. 29, the concepts described above may be implemented in various types of communication devices 200, such as those listed in the previous paragraph. The communication device 200 will generally include a control system 202, a baseband processor 204, transmit circuitry 206, receive circuitry 208, antenna switching circuitry 210, multiple antennas 212, and user interface circuitry 214. Herein, at least one or any combination of the control system 202, the baseband processor 204, the transmit circuitry 206, and the receive circuitry 208 may be implemented in the RF package 10 (e.g. implemented in the first flip-chip die 26, the second flip-chip die 30, and/or the extra flip-chip die 106) as illustrated in FIGS. 1A, 1B, 2A, and 2C and described above.

In a non-limiting example, the control system 202 can be a field-programmable gate array (FPGA) or an application-specific integrated circuit (ASIC), as an example. In this regard, the control system 202 can include at least a microprocessor(s), an embedded memory circuit(s), and a communication bus interface(s). The receive circuitry 208 receives radio frequency signals via the antennas 212 and through the antenna switching circuitry 210 from one or more base stations. A low noise amplifier and a filter of the receive circuitry 208 cooperate to amplify and remove broadband interference from the received signal for processing. Down conversion and digitization circuitry (not shown) will then down convert the filtered, received signal to an intermediate or baseband frequency signal, which is then digitized into one or more digital streams using an analog-to-digital converter(s) (ADC).

The baseband processor 204 processes the digitized received signal to extract the information or data bits conveyed in the received signal. This processing typically comprises demodulation, decoding, and error correction operations, as will be discussed in greater detail below. The baseband processor 204 is generally implemented in one or more digital signal processors (DSPs) and ASICs.

For transmission, the baseband processor 204 receives digitized data, which may represent voice, data, or control information, from the control system 202, which it encodes for transmission. The encoded data is output to the transmit circuitry 206, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 212 through the antenna switching circuitry 210. The multiple antennas 212 and the replicated transmit and receive circuitries 206, 208 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A radio frequency (RF) package comprising:
a carrier board;
an electronic module, which is attached to the carrier board via a plurality of contact structures and includes a module substrate, an interposer, a first flip-chip die, a first heat spreader, and a mold compound, wherein:
the interposer is attached to a top surface of the module substrate, the first flip-chip die is attached to a top surface of the interposer, and a first heat spreader is attached to the top surface of the interposer to provide a first air-cavity, within which the first flip-chip die is located;
the interposer, the first flip-chip die, and the first heat spreader are thermally coupled to each other;
the mold compound resides on the top surface of the module substrate and surrounds the interposer and the first heat spreader without being in contact with the first flip-chip die; and
a top surface of the electronic module is composed of at least a top surface of the first heat spreader and a top surface of the mold compound, a side surface of the electronic module is a combination of a side surface of the mold compound and a side surface of the module substrate, and a bottom surface of the electronic module is a bottom surface of the module substrate;
a shielding structure directly and completely covering the top surface of the electronic module and the side surface of the mold compound to provide a shielded module; and
a heat sink formed over the shielded module.

2. The RF package of claim 1, wherein:
the electronic module further includes a second flip-chip die and a second heat spreader;
the second flip-chip die is attached to the top surface of the interposer, and the second heat spreader, separate from the first heat spreader, is attached to the top surface of the interposer to provide a second air-cavity, within which the second flip-chip die is located;
the interposer, the second flip-chip die, and the second heat spreader are thermally coupled to each other;
the mold compound surrounds the second heat spreader without being in contact with the second flip-chip die; and
the top surface of the electronic module is further composed of a top surface of the second heat spreader.

3. The RF package of claim 2, wherein:
the first flip-chip die comprises gallium nitride (GaN), gallium arsenide (GaAs), or silicon; and
the second flip-chip die comprises GaN, GaAs, or silicon.

4. The RF package of claim 1, wherein the first flip-chip die includes a first die body, first interconnects extending outwardly from the first die body and coupled to the interposer via first solder caps, respectively, and first die vias extending through the first die body and coupled to corresponding first interconnects, respectively.

5. The RF package of claim 4, wherein the electronic module further comprises a first protection layer, which is located within the first air-cavity and at least encapsulates each of the first solder caps.

6. The RF package of claim 1, wherein:
the first heat spreader includes a first lid and a first periphery wall that extends outwardly from a periphery of a bottom surface of the first lid and is attached to the top surface of the interposer, such that the first air-cavity is formed under the first lid and surrounded by the first periphery wall; and
the first lid is formed over and thermally coupled to a backside of the first flip-chip die, and the first periphery wall surrounds the first flip-chip die.

7. The RF package of claim 6, wherein:
the interposer includes an interposer body and a plurality of interposer via structures, each of which is composed of a top via pad formed on a top surface of the interposer body, a through-silicon/silicon carbide via (TSV), and a bottom via pad formed on a bottom surface of the interposer body;
each TSV extends through the interposer body and is coupled between a corresponding top via pad on the top surface of the interposer body and a corresponding bottom via pad on the bottom surface of the interposer body;
the plurality of interposer via structures are separate from each other and formed of an electrically and thermally conductive material; and
certain ones of the plurality of interposer via structures are aligned with and thermally connected to the first periphery wall of the first heat spreader.

8. The RF package of claim 7, wherein:
the bottom surface of the first lid of the first heat spreader is thermally attached to the backside of the first flip-chip die through a first sintered layer; and
the first periphery wall of the first heat spreader is attached to the certain ones of the plurality of interposer via structures through a first sintered component, wherein each of the first sintered layer and the first sintered component has a thermal conductivity larger than 60 W/m·K.

9. The RF package of claim 7, wherein:
the electronic module further includes an extra flip-chip die attached to the backside of the first flip-chip die and located within the first air-cavity;
the first lid is formed over a backside of the extra flip-chip die, and the first periphery wall surrounds a combination of the first flip-chip die and the extra flip-chip die; and
the interposer, the first flip-chip die, the extra flip-chip, and the first heat spreader are thermally coupled to each other.

10. The RF package of claim 9, wherein:
the bottom surface of the first lid of the first heat spreader is thermally attached to the backside of the extra flip-chip die through a first sintered layer; and
the first periphery wall of the first heat spreader is attached to the certain ones of the plurality of interposer via structures through a first sintered component, wherein each of the first sintered layer and the first sintered component has a thermal conductivity larger than 60 W/m·K.

11. The RF package of claim 9, wherein:
the first flip-chip die includes a first die body, first interconnects extending outwardly from the first die body and coupled to certain other ones of the plurality of interposer via structures through first solder caps, respectively, first die vias extending through the first die body and coupled to corresponding first interconnects, respectively, and die via pads formed on a top surface of the first die body and coupled to corresponding first die vias, respectively; and
the extra flip-chip die includes a die body, interconnects extending outwardly from the die body and coupled to corresponding die via pads on the top surface of the first die body through solder caps, respectively, and die vias extending through the die body of the extra flip-chip die and coupled to corresponding interconnects of the extra flip-chip die, respectively.

12. The RF package of claim 11, wherein:
the electronic module further comprises a first protection layer and an extra protection layer;
the first protection layer is located within the first air-cavity and at least encapsulates each of the first solder caps; and
the extra protection layer is located within the first air-cavity and at least encapsulates each of the solder caps of the extra flip-chip die.

13. The RF package of claim 1, wherein the first heat spreader is formed of silicon carbide.

14. The RF package of claim 1, wherein the first heat spreader is at least 1.5 times larger than the first flip-chip die in horizontal dimensions.

15. The RF package of claim 1, wherein the module substrate is a laminate-based substrate.

16. The RF package of claim 1, wherein the shielding structure comprises multiple layers and is formed of stainless steel and copper.

17. The RF package of claim 1, wherein the plurality of a plurality of contact structures is configured as a Ball Grid Array (BGA).

18. The RF package of claim 1, wherein the plurality of a plurality of contact structures is configured as a Land Grid Array (LGA).

19. A communication device comprising:
a control system;
a baseband processor;
receive circuitry; and
transmit circuitry, wherein at least one or any combination of the control system, the baseband processer, the transmit circuitry, and the receive circuitry is implemented in an RF package, which has a carrier board, an electronic module attached to the carrier board via a plurality of contact structures, a shielding structure, and a heat sink, wherein:
the electronic module includes a module substrate, an interposer, a first flip-chip die, a first heat spreader, and a mold compound;
the interposer is attached to a top surface of the module substrate, the first flip-chip die is attached to a top surface of the interposer, and a first heat spreader is attached to the top surface of the interposer to provide a first air-cavity, within which the first flip-chip die is located;
the interposer, the first flip-chip die, and the first heat spreader are thermally coupled to each other;
the mold compound resides on the top surface of the module substrate and surrounds the interposer and the first heat spreader without being in contact with the first flip-chip die, such that a top surface of the electronic module is composed of at least a top surface of the first heat spreader and a top surface of the mold compound, a side surface of the electronic module is a combination of a side surface of the mold compound and a side surface of the module substrate, and a bottom surface of the electronic module is a bottom surface of the module substrate;
the shielding structure directly and completely covers the top surface of the electronic module and the side surface of the mold compound to provide a shielded module; and
the heat sink is formed over the shielded module.

20. A method of fabricating an RF package comprising:
forming an electronic module, wherein:
the electronic module includes a module substrate, an interposer, a first flip-chip die, a first heat spreader, and a mold compound;
the interposer is attached to a top surface of the module substrate, the first flip-chip die is attached to a top surface of the interposer, and a first heat spreader is attached to the top surface of the interposer to provide a first air-cavity, within which the first flip-chip die is located;
the interposer, the first flip-chip die, and the first heat spreader are thermally coupled with each other;
the mold compound resides on the top surface of the module substrate and surrounds the interposer and the first heat spreader without being in contact with the first flip-chip die, such that a top surface of the electronic module is composed of at least a top surface of the first heat spreader and a top surface of the mold compound, a side surface of the electronic module is a combination of a side surface of the mold compound and a side surface of the module substrate, and a bottom surface of the electronic module is a bottom surface of the module substrate;
forming a shielding structure directly and completely over the top surface of the electronic module and the side surface of the mold compound to provide a shielded module; and
attaching the shielded module to a carrier board via a plurality of contact structures.
